(19) United States
(12) Patent Application Publication
(10) Pub. No.: US 2006/0124925 A1
(43) Pub. Date: Jun. 15, 2006

(54) Electron device, operational device and display device

(76) Inventors: Hiroshi Kondo, Kanagawa (JP); Hitoshi Kondoh, Kanagawa (JP); Hidenori Tomono, Kanagawa (JP); Koh Fujimura, Tokyo (JP); Takanori Tano, Kanagawa (JP); Yukio Hirano, Chiba (JP); Noriaki Narita, Chiba (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/287,325

(22) Filed: Nov. 28, 2005

(30) Foreign Application Priority Data
Nov. 30, 2004 (JP) 2004-347044
Sep. 29, 2005 (JP) 2005-284928

(51) Int. Cl. H01L 29/08; H01L 27/10; H01L 29/739

(52) U.S. Cl. 257/40; 257/202

(57) ABSTRACT

An electron device includes at least an electrode layer, a semiconductor layer and an insulator layer laminated on a substrate, wherein the insulator layer contains a polyimide material obtained by using at least one of a polyamic acid and derivatives of the polyamic acid, the polyamic acid being obtained by reacting one or more of tetracarbonic acid dianhydride compounds selected from the group consisting of a tetracarbonic anhydride and derivatives of the tetracarbonic anhydride, with a diamine compound, the tetracarbonic dianhydride compound containing one or more components of tetracarbonic dianhydride compound selected from a specific group of tetracarbonic acid dianhydrides and the derivatives thereof.

### BACKGROUND OF THE INVENTION

The present invention relates to electron devices, operational devices and display devices.

A flat panel display device such as a liquid crystal display device, PDP (plasma display panel), organic EL (electro-luminescence) device, and the like, includes parts where a thin film is patterned according to passive elements such as an electrode or active elements such as an MIM (metal-insulator-metal) device, a TFT (thin-film transistor), and the like, or a light-emitting device.

Generally, patterning of a thin film is achieved by a photolithographic process, while the use of photolithographic process causes the problem of increased cost because of high cost of the facility needed for the process and because of long processing time.

In view of the foregoing problem, attempts are being made to form patterns by means of printing technology in the prospect of reducing the production cost of electron devices.

More specifically, there is disclosed a process of conducting at least a part of the patterning process of a thin film in the process of fabricating a TFT, by way of intaglio offset printing in place of using photolithography (Patent Reference 1). Further, there is a technology of forming a metal interconnection pattern by an ink-jet process that uses nano-particle ink (Non-Patent Reference 1).

On the other hand, from the viewpoint of low production cost and capability of processing a large area and further in view of achieving the functions not attainable by inorganic materials, there is proposed the technology of fabricating an electron device by using an organic material or by using such an organic material at least in a part thereof.

Thus, it is known in the art to form a pattern of gate electrode layer, source electrode layer and drain electrode layer by an organic material by using an ink-jet process (Non-Patent Reference 2 and 3). However, this conventional process requires a long processing time in order for forming a rib of polyimide, and the advantage of using low-cost ink-jet process is not attained.

Further, there is disclosed a method of forming a conductive film pattern by: forming a part affiliating with a liquid by way of decomposing and removing a part of an organic molecular film formed on a substrate and constituting a liquid-repellent part, by irradiating ultraviolet light; and applying a liquid containing conductive particles to the liquid-affiliating part thus formed (Patent Reference 2). However, such an approach has a drawback in that the function of the film is limited in view of the fact that the organic molecular film itself does not provide a useful function other than controlling of critical surface tension.

Further, there is proposed the use of a material of any of polyimide, polyamide, polyester and polyacrylate for the gate insulation film of a MOS TFT, wherein it is disclosed to form such a gate insulation film simply by a coating process (Patent References 3 and 4). However, there is a problem that good insulation performance is not attained by merely limiting the material of the insulation film.

### REFERENCES

Patent Reference 1 Japanese Laid-Open Patent Application 2002-268585 official gazette
Patent Reference 2 Japanese Laid-Open Patent Application 2002-164635 official gazette
Patent Reference 3 Japanese Laid-Open Patent Application 2003-258256 official gazette
Patent Reference 4 Japanese Laid-Open Patent Application 2003-309268 official gazette
Non-Patent Reference 1 SOCIETY for INFORMATION DISPLAY 2002 INTERNATIONAL SYMPOSIUM DIGEST OF TECHNICAL PAPER•Volume XXXIII, p. 753-755
Non-Patent Reference 2 SOCIETY for INFORMATION DISPLAY 2002 INTERNATIONAL SYMPOSIUM DIGEST OF TECHNICAL PAPERS VOLUME XXXIII, p. 1017-1019
Non-Patent Reference 3 Science 290, p. 2123-2126 (2000)

### SUMMARY OF THE INVENTION

It is the object of the present invention to eliminate the foregoing problems by an electron device having an insulator layer of good insulation performance and capable of being fabricated with low cost. Further, the present invention provides an operational device and a display device that uses such an electron device.

In a first aspect, the present invention provides an electron device comprising at least an electrode layer, a semiconductor layer and an insulator layer laminated on a substrate,

said insulator layer containing a polyimide material obtained by using at least one of a polyamic acid and a derivative of said polyamic acid, said polyamic acid being obtained by reacting one or more of tetracarbonic acid dianhydride compounds selected from the group consisting of a tetracarbonic anhydride and derivatives of said tetracarbonic anhydride, with a diamine compound,

said tetracarbonic dianhydride compound containing one or more components of tetracarbonic dianhydride compound selected from the group consisting of tetracarbonic acid dianhydrides represented by structural formulae of: 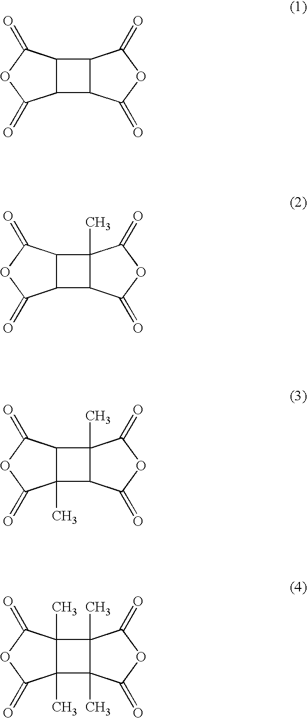 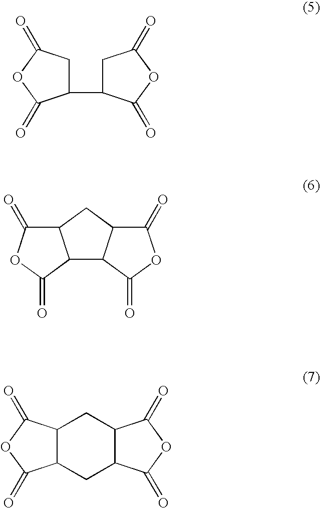 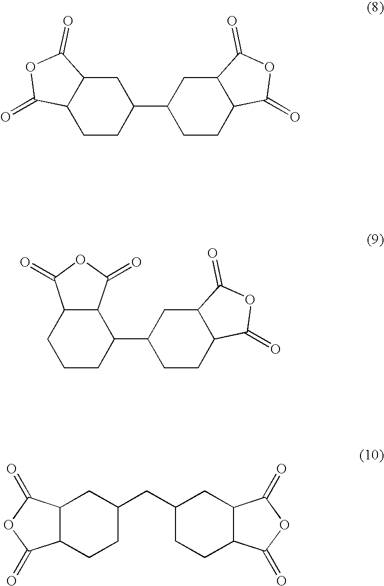 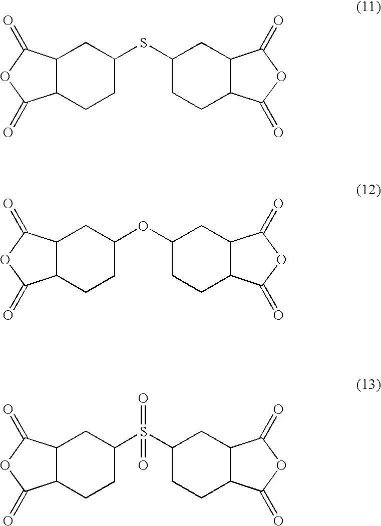 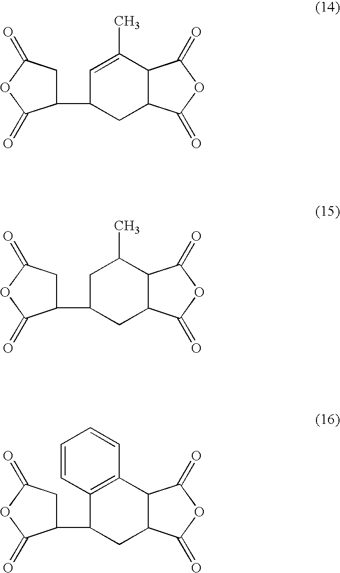 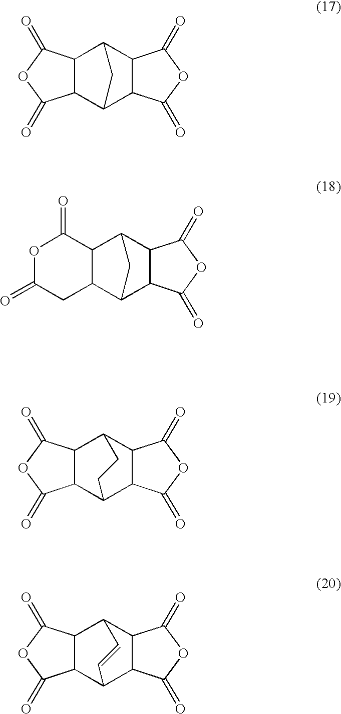 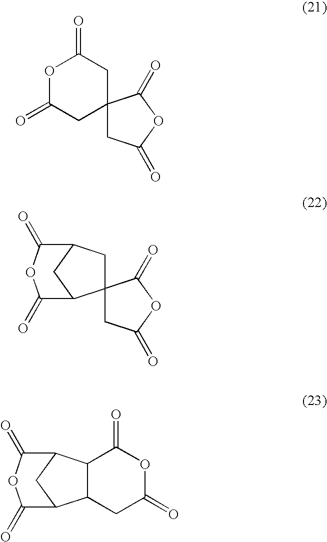 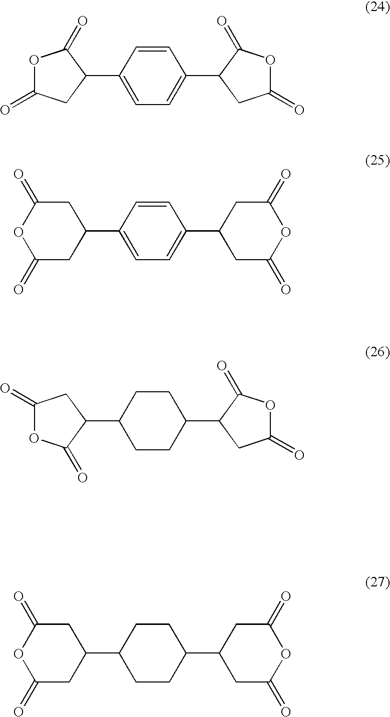 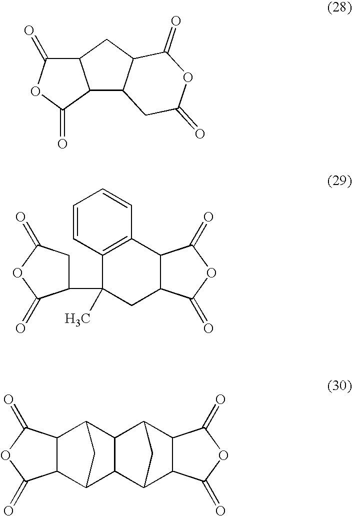 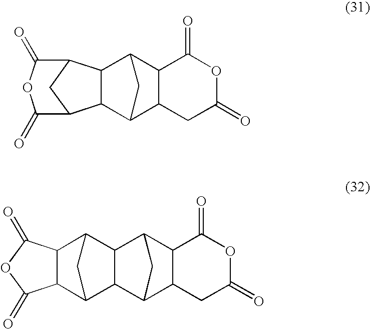 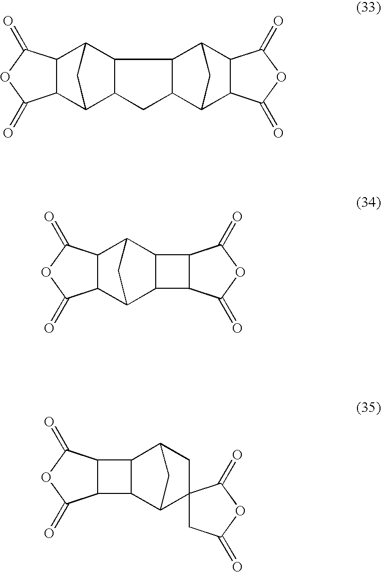 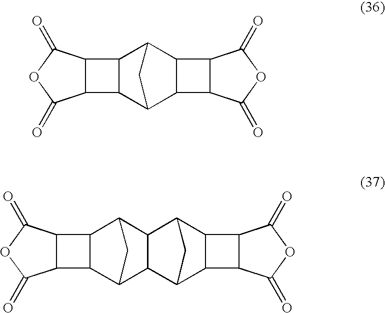
and derivatives of said tetracarbonic acid dianhydrides. According to the first aspect of the present invention, it becomes possible to provide an electron device having an insulator layer of good insulation performance and it becomes possible to fabricate the electron device with low cost as a result of the use of the insulator layer as set forth above.

In a second aspect, the present invention provides the electron device of the first aspect, such that said component of said tetracarbonic acid dianhydride compounds is contained with a mole fraction of 0.5 or more but not exceeding 1 with respect to said tetracarbonic acid dianhydride compounds. According to the second aspect of the present invention, it becomes possible to improve the insulation performance of the insulator layer by setting the mole fraction of the component of the tetracarbonic acid dianhydride compound as set forth above.

In a third aspect, the present invention provides an electron device comprising at least an electrode layer, a semiconductor layer and an insulator layer laminated on a substrate, said insulator layer containing a polyimide material obtained by using a polyamic acid or a derivative of said polyamic acid, said polyamic acid being obtained by causing to react one or more of tetracarbonic acid dianhydride compounds selected from the group consisting of a tetracarbonic acid dianhydride and a derivative of said tetracarbonic acid dianhydride with a diamine compound,

said tetracarbonic dianhydride compound containing one or more components of tetracarbonic dianhydride compound selected from the group of tetracarbonic acid dianhydrides represented by structural formulae of: 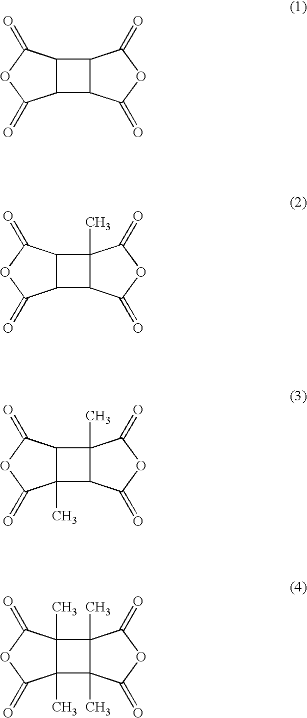 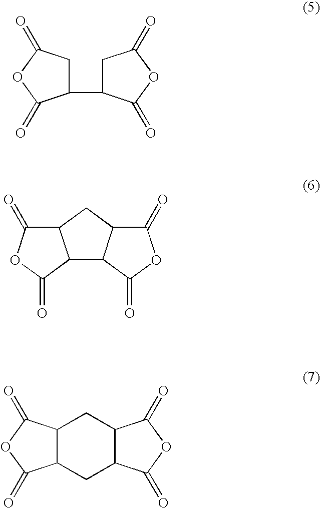 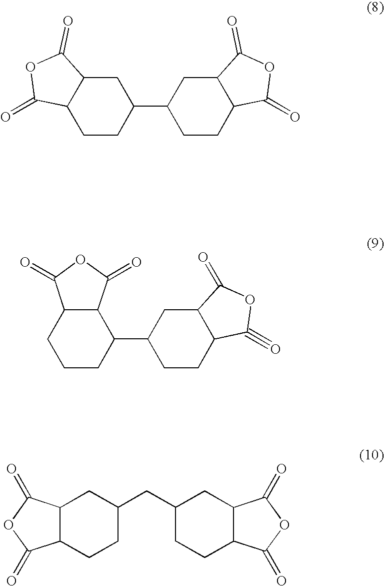 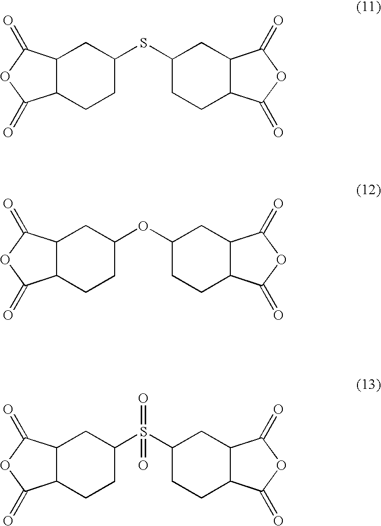 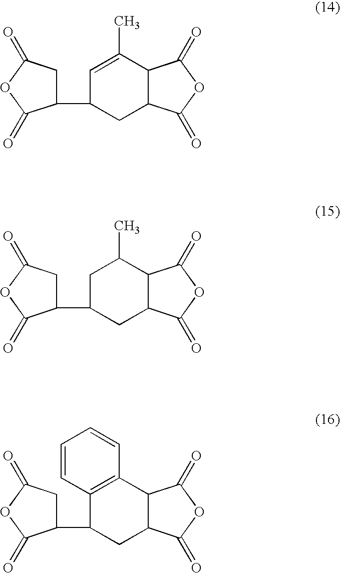 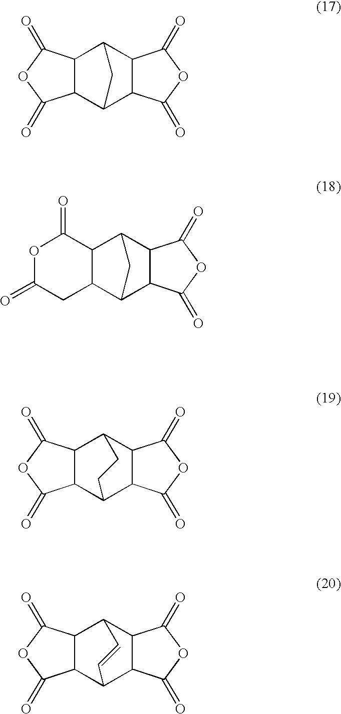 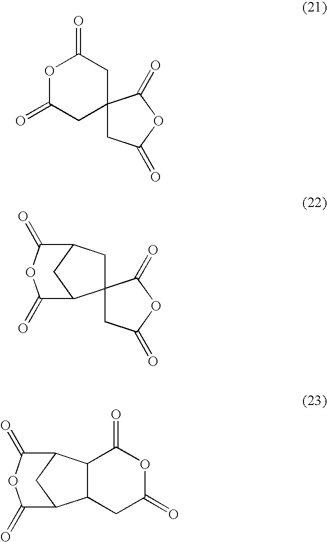 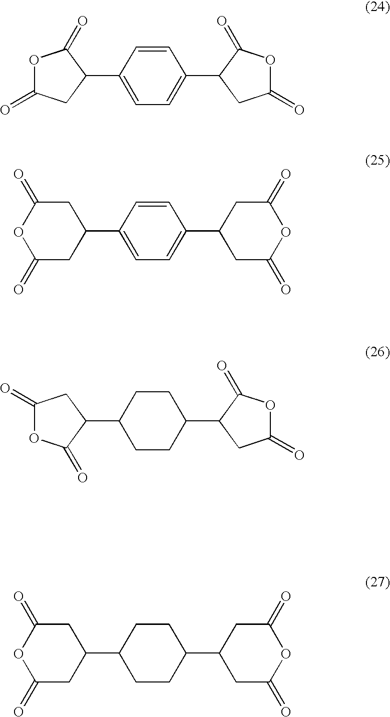 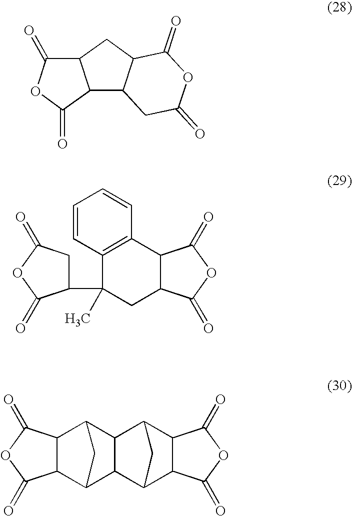 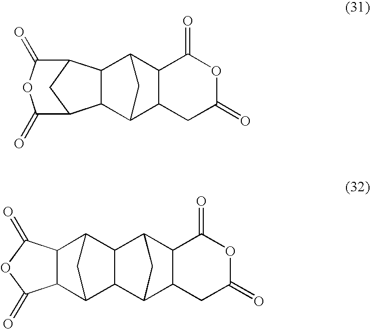 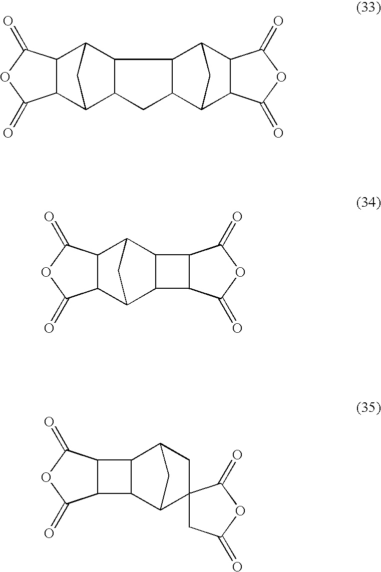 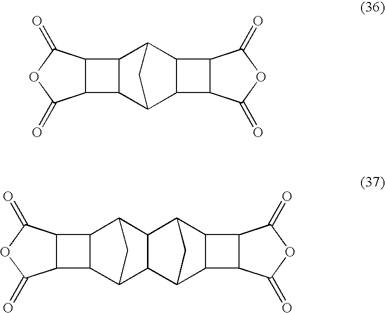 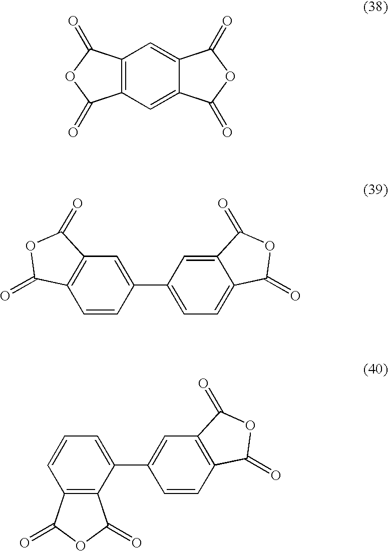 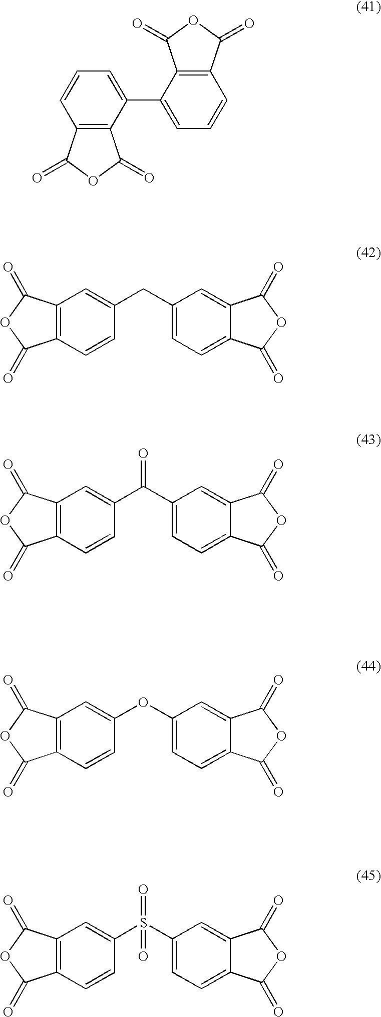 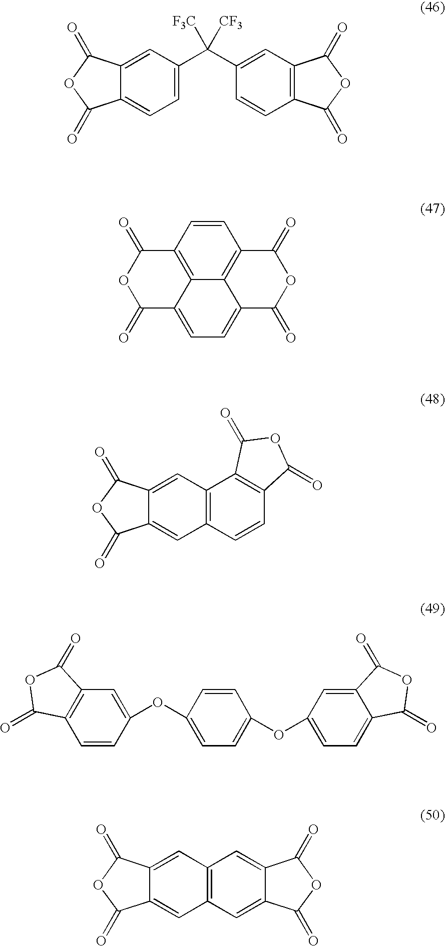
and derivatives of said tetracarbonic acid dianhydride,

said diamine compound containing a diamine having a side chain. Here, it should be noted that, in the specification and claims of the present invention, “diamine having a side chain” means a diamine that has a side chain in the case the chain connecting two amino groups are regarded as a principal chain. According to the third aspect of the present invention, it becomes possible to provide an electron device in which the insulator layer has good insulation performance and can be fabricated with low cost, by using the insulator layer as set forth above.

In a fourth aspect, the present invention provides the electron device of the third aspect, such that said diamine having a side chain comprises one or more compounds selected from the group of the compounds represented as

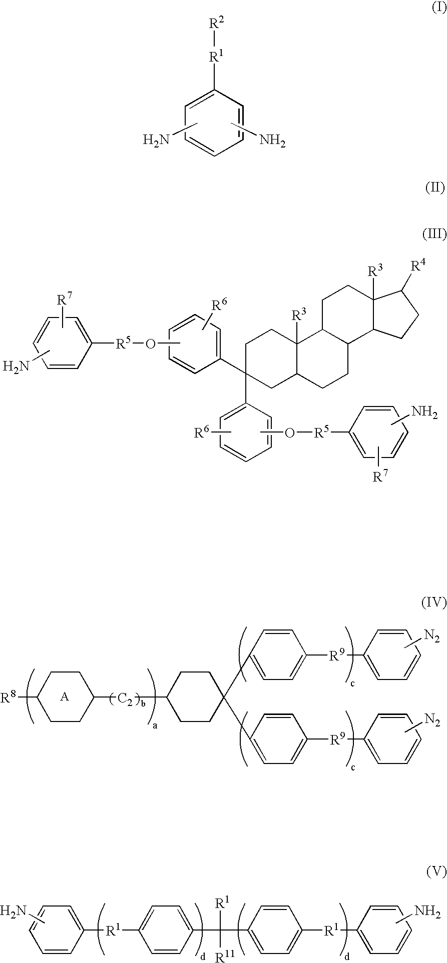

wherein R¹ is any of a single bond, an oxy group, a carbonyl group, —COO—, —OCO—, —CONH, —CH₂O—, CF₂O—, or —(CH₂)ₑ—,

R² is a group having a steroid structure and having a general formula of 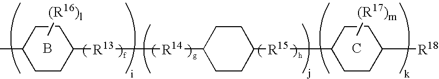
or an alkyl group or a phenyl group containing one or more, but not exceeding twenty, carbon atoms,

R³ is, independently in each occurrence thereof, a hydrogen atom or a methyl group,

R⁴ is, independently in each occurrence thereof, a hydrogen atom or an alkyl group containing one or more, but not exceeding twenty, carbon atoms,

R⁵ is, independently in each occurrence thereof, any of a single bond, a carbonyl group or a methylene group,

each of R⁶ and R⁷ is, independently in each occurrence thereof, any of a hydrogen atom or an alkyl group or a phenyl group containing one or more, but not exceeding twenty. carbon atoms,

R⁸ is a hydrogen atom or an alkyl group containing one or more, but not exceeding twenty, carbon atoms,

R⁹ is, independently in each occurrence thereof, an oxy group or an alkylene group containing one or more, but not exceeding six, carbon atoms,

each of R¹⁰ and R¹¹ is, independently in each occurrence thereof, any of a hydrogen atom, an alkyl group or a perfluoroalkyl group having one or more, but not exceeding twenty, carbon atoms, at least one of R¹⁰ and R¹¹ being an alkyl group or a perfluoroalkyl group containing three or more carbon atoms,

R¹² is, independently in each occurrence thereof, an oxy group or an alkylene group containing one or more, but not exceeding six, carbon atoms,

each of R¹³, R¹⁴ and R¹⁵ is, independently in each occurrence thereof, any of a single bond, an oxy group, —COO—, —OCO—, —CONH—, an alkylene group containing one or more, but not exceeding four, carbon atoms, or an alkyleneoxy group containing one or more, but not exceeding three, carbon atoms,

each of R¹⁶ and R¹⁷ is, independently in each occurrence thereof, any of a hydrogen atom, a fluoro group or a methyl group,

R¹⁸ is any of a hydrogen atom, a fluoro group, a chloro group, a cyano group, an alkyl group containing one or more, but not exceeding twenty, carbon atoms, an alkoxy group containing one or more, but not exceeding twenty, carbon atoms, an alkoxyalkyl group containing two or more, but not exceeding twenty, carbon atoms, a fluoromethyl group, a difluoromethyl group, a trifluoromethyl group, a fluoromethoxy group, difluoromethoxy group or a trifluoromethoxy group,

said ring A is any of a 1,4-phenylene group or 1,4-cyclohexylene group,

each of said rings B and C is any of a 1,4-phenylene group or 1,4-cyclohexylene group,

a is 0 or 1,

b is an integer of 0 or larger but not exceeding 2,

c is, independently in each occurrence thereof, an integer of 0 or 1,

d is, independently in each occurrence thereof, an integer of 0 or 1,

e is an integer of 1 or larger but not exceeding 6,

each of f, g and h is, independently in each occurrence thereof, an integer of 0 or larger but not exceeding 4,

each of i, j and k is, independently in each occurrence thereof, an integer of 0 or larger but not exceeding 3,

a total of i, j and k being 1 or larger,

each of 1 and m having, independently in each occurrence thereof, a value of any of 1 or 2. According to the fourth aspect of the present invention, it becomes possible to decrease the critical surface tension of the insulator layer by using the diamine as set forth above.

In a fifth aspect, the present invention provides the electron device of the third or fourth aspect of the present invention, such that a mole fraction of said diamine having said side chain with regard to said diamine compounds is set to 0.3 or more nut not exceeding 1. According to the fifth aspect of the present invention, it is possible to decrease the critical surface tension of the insulator layer by setting the diamine mole fraction as set forth above.

In a fifth aspect, the present invention provides the electron device of any of the first through fifth aspects, such that said polyimide material is obtained by using at least one of said polyamic acid and said polyamic acid derivative and an imidation catalyst. According to the sixth aspect, it becomes possible to obtain the polyimide material by causing the imidization reaction at low temperature.

In a seventh aspect, the present invention provides the electron device of any of the first through sixth aspects, such that said semiconductor layer comprises an organic semiconductor material. According to the seventh aspect of the present invention, it is possible to conduct the film formation process at low temperature with the use of organic semiconductor material.

In an eighth aspect, the present invention provides the electron device of any of the first through seventh aspects, such that said electrode layer includes a first electrode layer and a second electrode layer, said second electrode layer comprising a pair of electrode patterns disposed with a mutual separation from each other, said first electrode layer, said insulator layer, said second electrode layer and said semiconductor layer are laminated consecutively over said substrate,

said electrode patterns of said second electrode layer being formed in correspondence to a region of said insulator layer provided with energy and having a larger critical surface tension as compared with a region not provided with said energy. According to the eighth aspect of the present invention, it becomes possible to fabricate the electron device with a simple process.

In a ninth aspect, the present invention provides the electron device of the eighth aspect, such that said insulator layer comprises two or more polyimide materials, such that said insulator layer has a concentration gradient of polyimide in a thickness direction thereof. According to the ninth aspect of the present invention, it is possible to decrease the critical surface tension of the insulator layer.

In a tenth aspect, the present invention provides the electron device of any of the first through seventh aspects, such that said insulator layer comprises a first insulator layer and a second insulator layer, said electrode layer comprises a first electrode layer including a pair of electrode patterns disposed with a mutual separation from each other and a second electrode layer, said first insulator layer, said electrode patterns of said first electrode layer, said semiconductor layer, said second insulator layer and said second electrode layer are laminated consecutively over said substrate,

wherein said first electrode layer is formed on said first insulator layer in correspondence to a region thereof where energy is provided and having a higher surface tension as compared with a region not provided with said energy. According to the tenth aspect of the present invention, it becomes possible to fabricate the electron device by a simple process.

In an eleventh aspect, the present invention provides the electron device of the tenth aspect such that said first insulator layer comprises two or more polyimide materials, said first insulator layer having a concentration gradient of polyimide in a thickness direction thereof. According to the eleventh aspect of the present invention, it becomes possible to decrease the critical surface tension of the insulator layer.

In a twelve aspect, the present invention provides the electron device of any of the eight through eleventh aspects such that said energy is provided by ultraviolet radiation. According to the twelfth aspect of the present invention, it becomes possible to form miniaturized patterns.

In a thirteenth aspect, the present invention provides the electron device of any of the eight through twelfth aspects, such that at least one of said first electrode layer and said second electrode layer is formed by an ink-jet process. According to the thirteenth aspect of the present invention, it becomes possible to form miniaturized patterns.

In a fourteenth aspect, the present invention provides an operational device that includes the electron device of any of the first through thirteenth aspects. According to the fourteenth aspect of the present invention, it becomes possible to provide a low-cost operational device.

In a fifteenth aspect, the present invention provides a display device that uses the electron device of any of the first through thirteenth aspects. According to the fifteenth aspect of the present invention, it becomes possible to fabricate the display device with low cost.

According to the present invention, it becomes possible to provide an electron device having an insulator layer of good insulation performance with low cost. Further, it becomes possible to provide an operational device and a display device by using such an electron device.

### BRIEF DESCRIPTION OF THE DRAWINGS

FIG. 1, is a diagram showing the relationship between a critical surface tension and the mobility of semiconductor.

FIG. 2 is a diagram showing an example of the construction of the electron device of the present invention;

FIG. 3 is a diagram showing another example of the construction of the electron device of the present invention;

FIGS. 4A-4E are diagrams schematically showing the concentration profile of the insulator layer in a thickness direction thereof;

FIG. 5 is a diagram showing an example of patterning of electrode in the present invention;

FIG. 6 is a circuit diagram showing an example of the operational device of the present invention;

FIG. 7 is a circuit diagram showing an example of the display device of the present invention;

FIG. 8 is a diagram showing the evaluation apparatus of a volume resistivity;

FIG. 9 is a diagram showing the result of evaluation of the films obtained by the present invention; and

FIG. 10 is a diagram showing the construction of the evaluation apparatus for evaluating the shape and mobility of the electron device.

### DETAILED DESCRIPTION OF THE INVENTION

Next, the present invention will be explained with reference to the drawings.

The electron device of the present invention includes devices such as a MIS diode and a MOS transistor in which at least an electrode layer, a semiconductor layer and an insulator layer are laminated on a substrate, while it should be noted that the present invention by no means limited to the foregoing specific devices.

In the present embodiment, the insulator layer contains a polyimide material A obtained by using at least one of a polyamic acid A and a derivative thereof, said polyamic acid A being obtained by reacting one or more of tetracarbonic acid dianhydride compounds A selected from the group consisting of a tetracarbonic anhydride and derivatives thereof, with a diamine compound A,

said tetracarbonic dianhydride compound A containing, as a component A of said tetracarbonic dianhydride compound, one or more of tetracarbonic acid dianhydrides selected from the group consisting of a tetracarbonic acid dianhydride having a structural formula represented by any of: 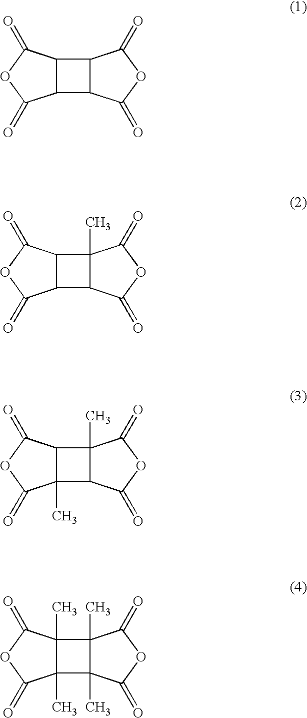 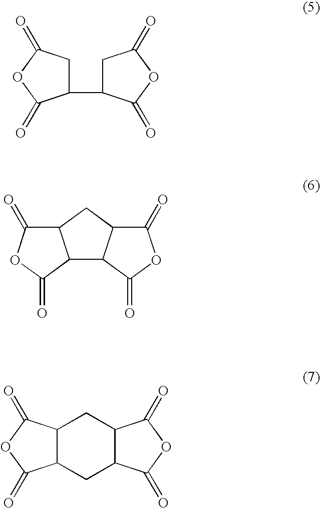 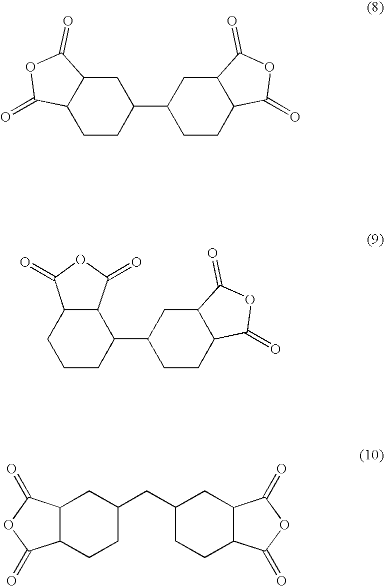 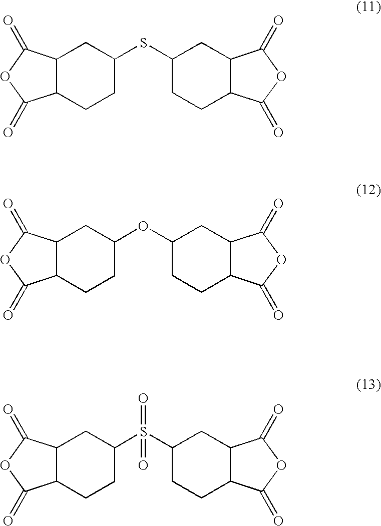 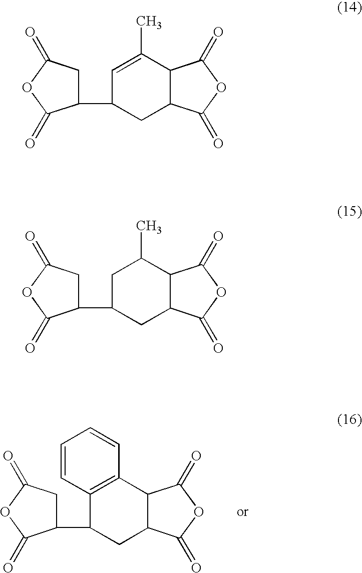 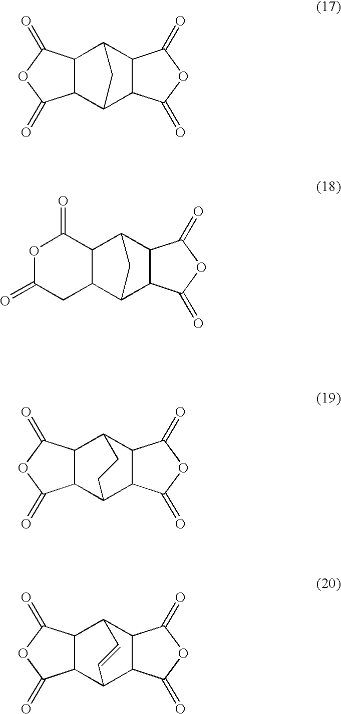 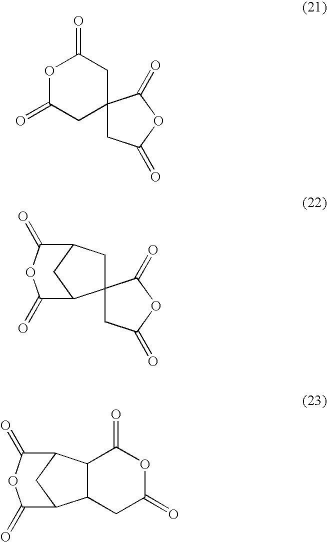 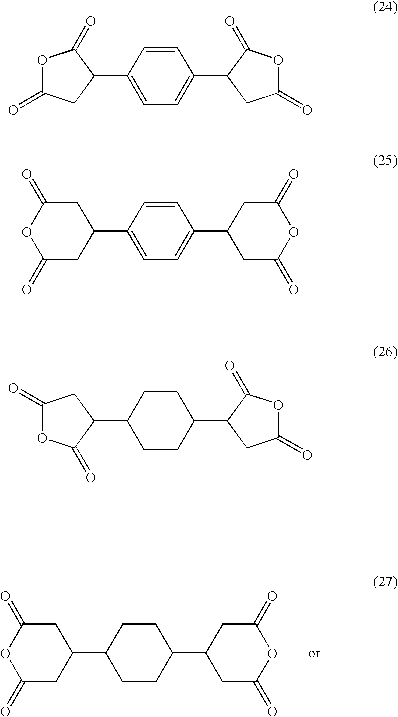 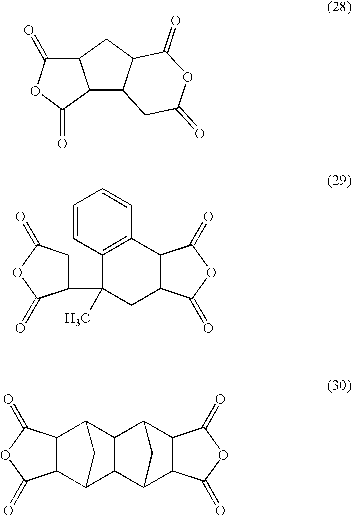 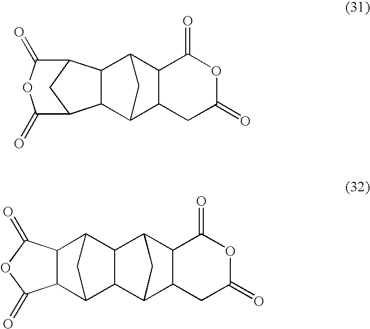 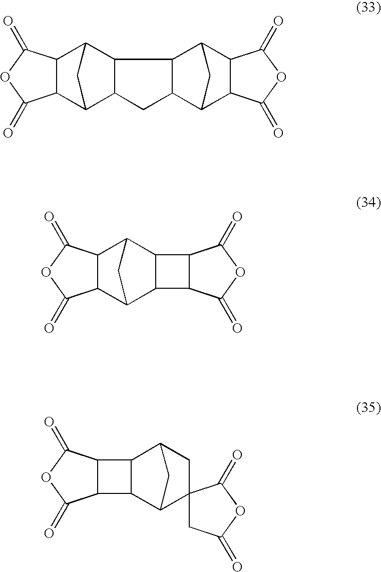 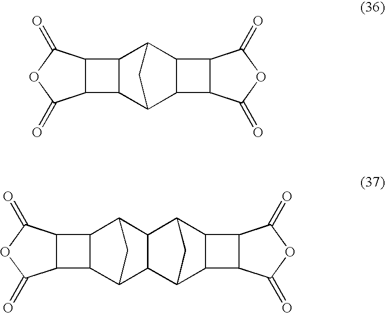
and derivatives of said tetracarbonic acid dianhydride.

As a result, it becomes possible to form the insulator layer by a coating process, and the electron device can be fabricated with low cost. Further, it becomes possible to form the insulator layer to have good insulation performance, and the reliability of the electron device is improved.

For the derivative of the polyamic acid, it is possible use any of: a polyimide resin formed by a complete or partial dehydrating ring-closure reaction of a polyamic acid; a polyamic acid ester in which all or a part of carbonic acid of a polyamic acid is esterified; a polyamic acid-polyamide copolymer obtained by substituting a part of the tetracarbonic acid dianhydride with a carbonic acid halide or the like; a polyamide imide resin formed by applying a total or partial dehydration ring-closure reaction to a polyamic acid-polyamide copolymer; and the like.

For the derivative of the tetracarbonic acid dianhydride, it is possible to use a tetracarbonic acid derivative such as tetracarbonic acid, tetracarbonic acid dialkylester dihalide, and the like. Thereby a part of the acid anhydride of the tetracarbonic acid dianhydride compound may be substituted by a dicarbonic acid halide

In order to improve the insulating performance of the insulator layer, it is preferable that the component A of the tetracarbonic acid dianhydride compound is at least one of the tetracarbonic acid dianhydride and derivatives thereof represented by the structural formulae (1)-(7) and (14)-(23), more preferably at least one of the tetracarbonic acid dianhydride and derivatives thereof represented by the structural formulae (1), (6), (7) and (17)-(23).

In the present invention, it is preferable, in order to form a polyimide material film by coating, that at least one of the polyamic acid A and the derivative thereof is soluble to a solvent. Thus, while the component A of the tetracarbonic acid dianhydride compound may be chosen appropriately, it is particularly preferable, in order to obtain a soluble polyimide resin as a derivative of the polyamic resin, to use a tetracarbonic acid dianhydride shown by the structural formulae (5), (14)-(16), (18) and (21)-(23) and a derivative thereof, for the component A of the tetracarbonic acid dianhydride compound.

It should be noted that the method of making the tetracarbonic acid dianhydride represented by the foregoing structural formulae can be found in various literatures. For example, the method of forming the compound of the structural formula (1) is given in the Japanese Laid-Open Patent Application 59-212495 official gazette; the method of forming the compounds of the structural formulae (2) and (3) is given in the Japanese Laid-Open Patent Application 3-137125 official gazette; the method of forming the compound of the structural formula (4) is given in the Japanese Laid-Open Patent Application 2003-192685 official gazette; the method of forming the compounds of the structural formulae (7), (8), (10) and (12) is given in the Japanese Laid-Open Patent Application 8-325196 official gazette; the method of forming the compound of the structural formula (14) is given in the Japanese Laid-Open Patent Application 55-36406 official gazette; the method of forming the compounds of the structural formulae (16) and (29) is given in the Japanese Laid-Open Patent Application 58-170776 official gazette; the method of forming the compound of the structural formula (17) is given in the Japanese Laid-Open Patent Application 63-57589 official gazette; the method of forming the compound of the structural formula (18) is given in the Japanese Laid-Open Patent Application 59-170087 official gazette; the method of forming the compounds of the structural formulae (23) and (28) is given in the Japanese Laid-Open Patent Application 58-109479 official gazette; the method of forming the compounds of the structural formulae (24) and (25) is given in the Japanese Laid-Open Patent Application 8-259949 official gazette, the method of forming the compounds of the structural formulae (26) and (27) is given in the Japanese Laid-Open Patent Application 2003-313180 official gazette; the method of forming the compound of the structural formula (30) is given in the Japanese Laid-Open Patent Application 2-235842 official gazette; the method of forming the compounds of the structural formulae (31), (32) and (33) is given in the Japanese Laid-Open Patent Application 2-149539 official gazette; the method of forming the compound of the structural formula (34) is given in the Japanese Laid-Open Patent Application 2003-137843 official gazette; the method of forming the compound of the structural formula (35) is given in the Japanese Laid-Open Patent Application 2004-18422 official gazette; the method of forming the compound of the structural formula (36) is given in the Japanese Laid-Open Patent Application 2002-316990 official gazette; and the method of forming the compound of the structural formula (37) is given in the Japanese Laid-Open Patent Application 2003-96070 official gazette.

In order to enhance the insulation performance of the insulator layer, it is preferable to set the mole fraction of the component A of the tetracarbonic acid dianhydride compound with respect to the tetracarbonic acid dianhydride compound A to 0.5 or more but not exceeding 1, and more preferably 0.7 or more but not exceeding 1.

For the diamine compound A, it is possible, while not limited, to use the diamines having the formulae (51)-(94) as noted below:

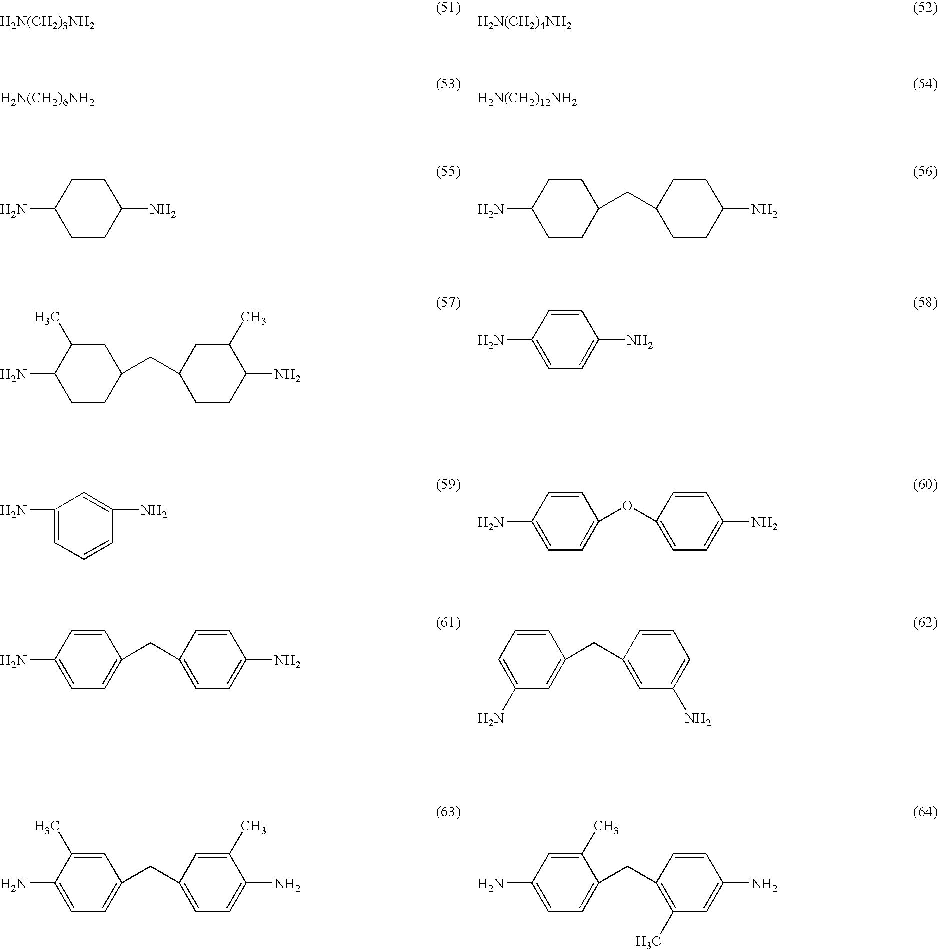

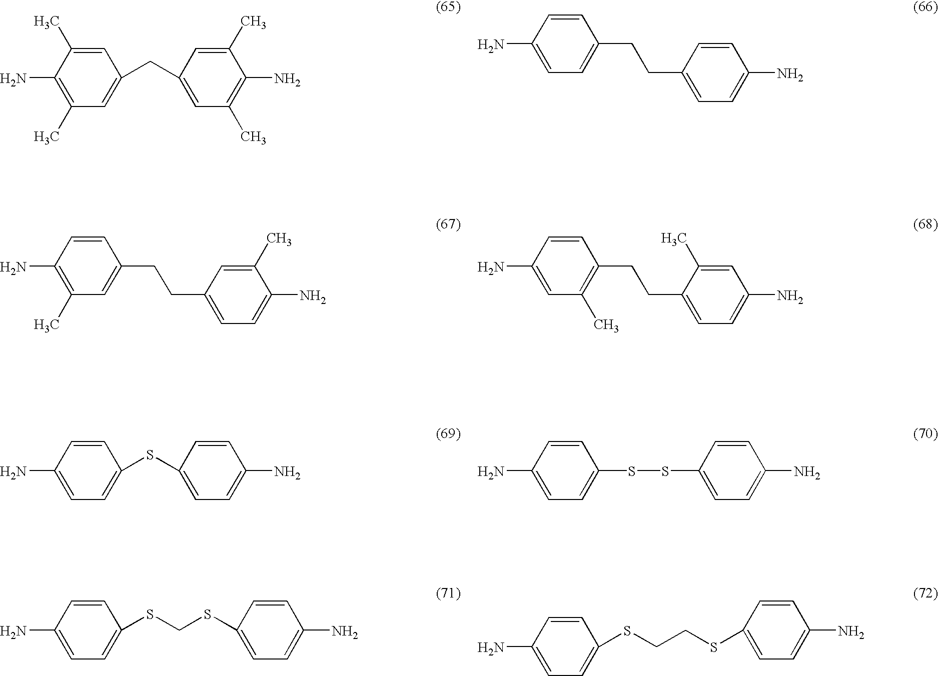

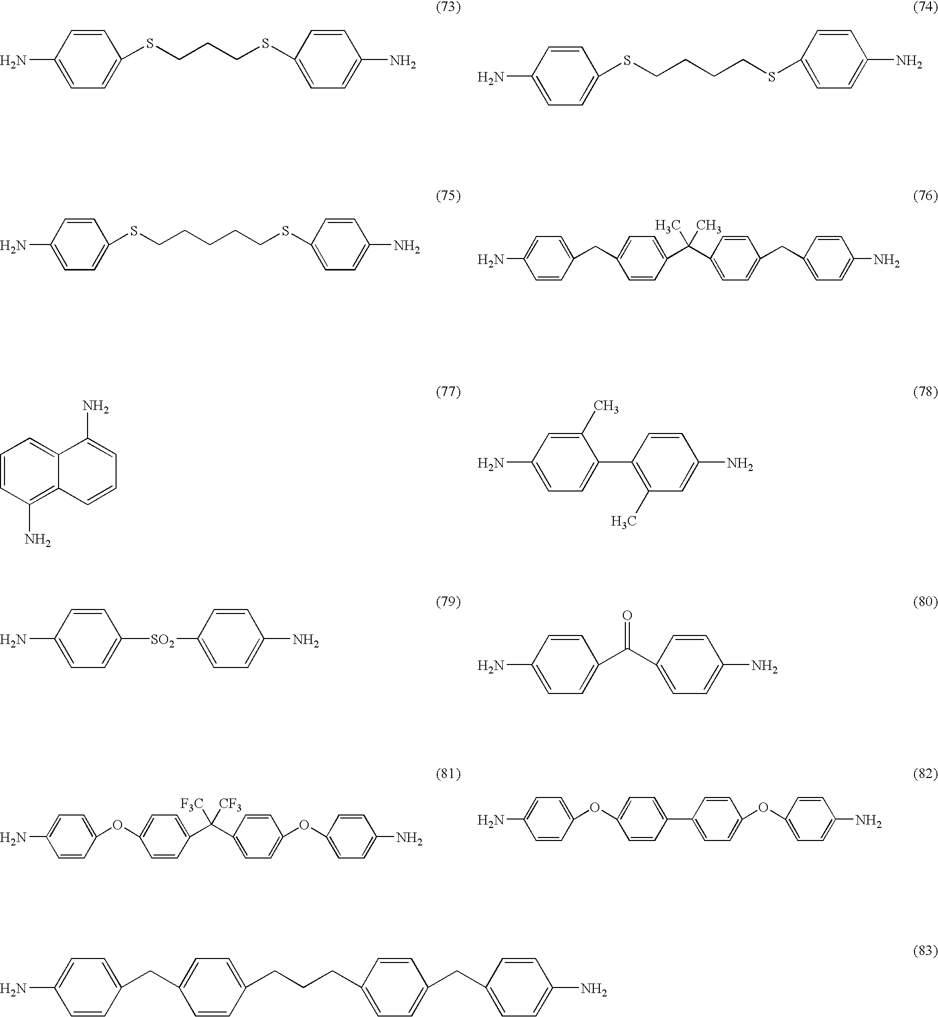

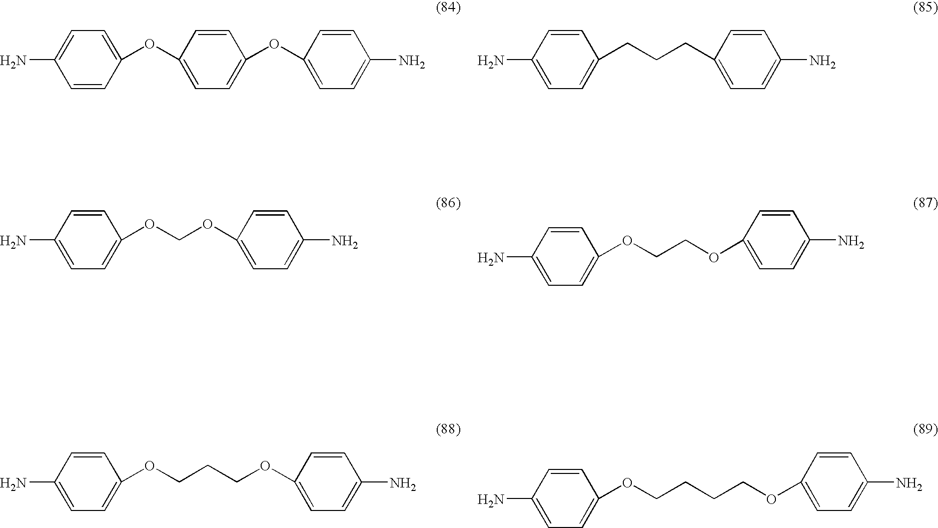

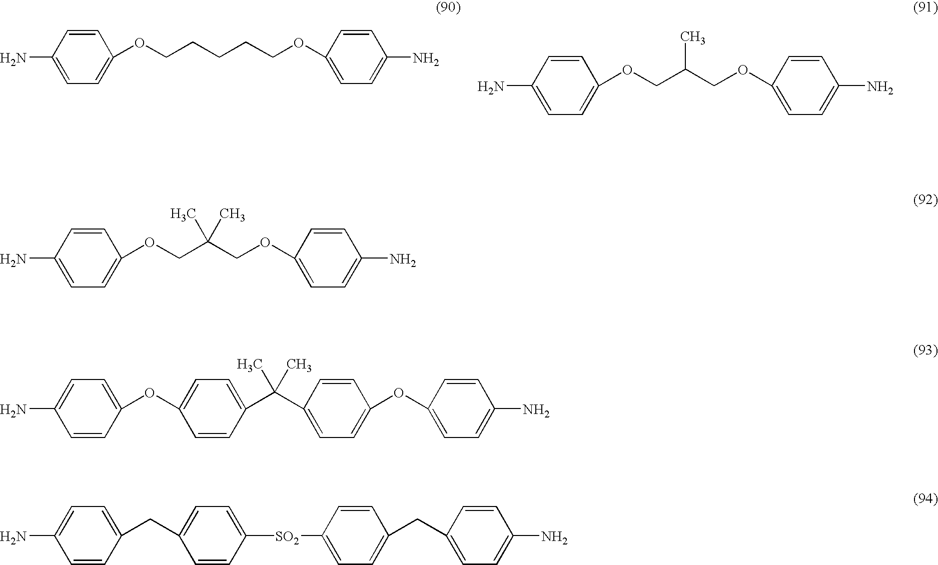

Further, for the diamine compounds A other than those noted above, siloxane series diamines having a siloxane bond may be used. While the siloxane series diamine is not limited, it is preferable to use the compound having a general formula represented as 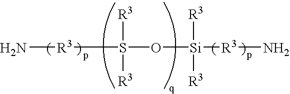
wherein each of R³⁰ and R³¹ is, independently in each occurrence thereof, an alkyl group having one or more, but not exceeding three, carbon atoms or a phenyl group, R³² is any of methylene, phenylene or a phenylene group substituted with alkyl, p is an integer of one or more but not exceeding six, q is an integer of one or more but not exceeding ten. Thereby, it is possible to use a single compound or a mixture of two or more compounds for the diamine compound A.

At the time of the reaction, it is also possible to add monoamine in addition to the diamine compound A as an end stopper.

In the present invention, the insulator layer contains a polyimide material B obtained by using at least one of a polyamic acid B and a derivative thereof, the polyamic acid B being obtained by reacting one or more tetracarbonic acid dianhydride compounds B selected from the group consisting of tetracarbonic acid dianhydrides and derivatives thereof and a diamine compound B, the tetracarbonic acid dianhydride compounds B containing one or more components B of tetracarbonic acid dianhydride compounds selected from the group of tetracarbonic acid dianhydrides represented by formulae (1)-(50) as: 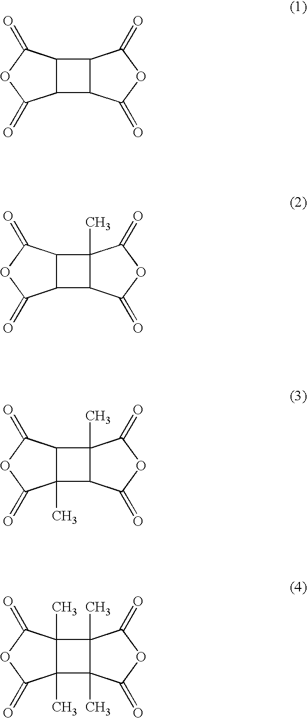 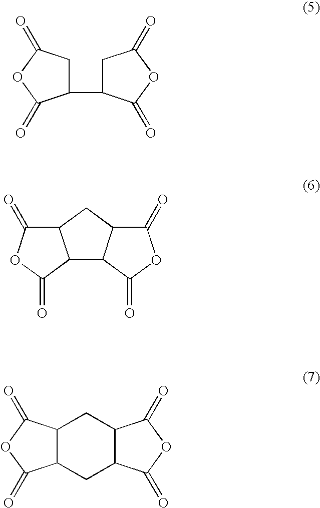 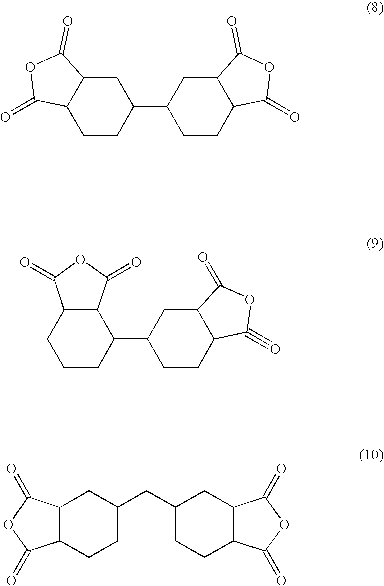 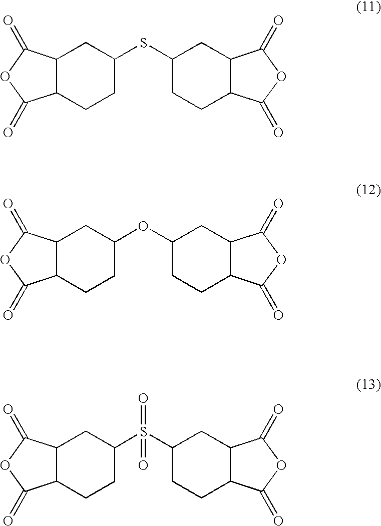 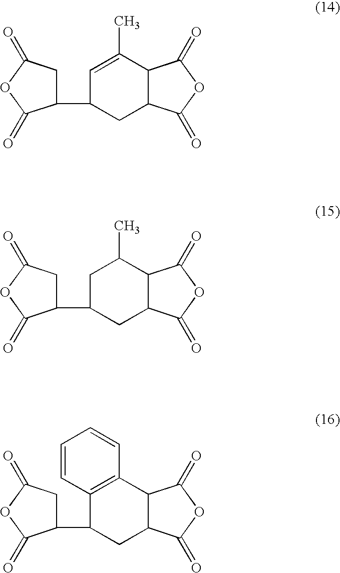 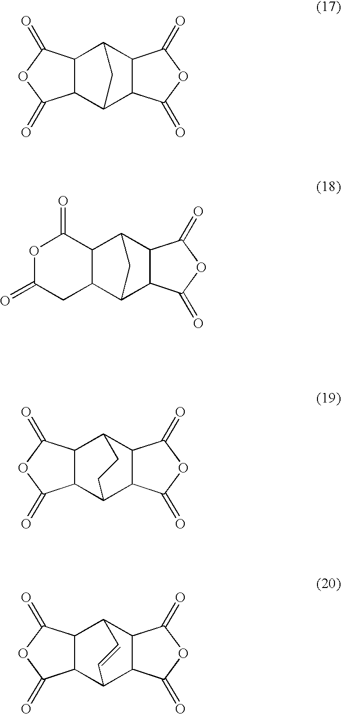 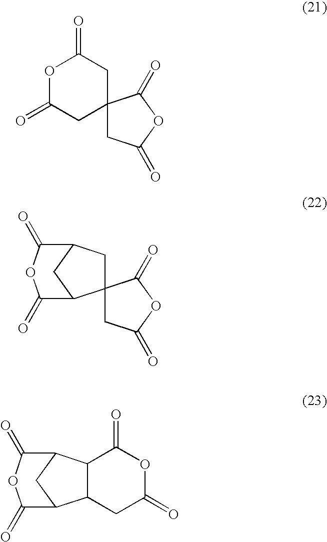 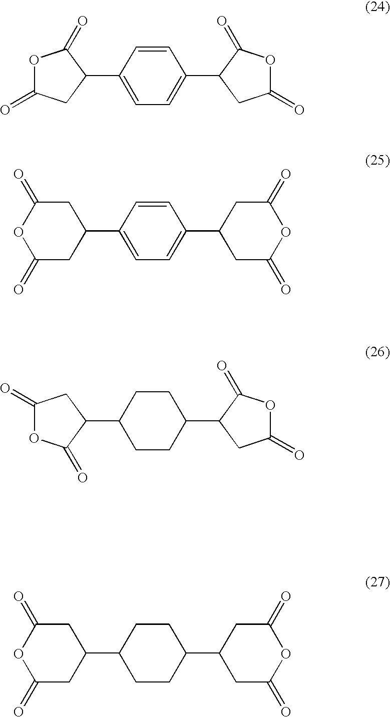 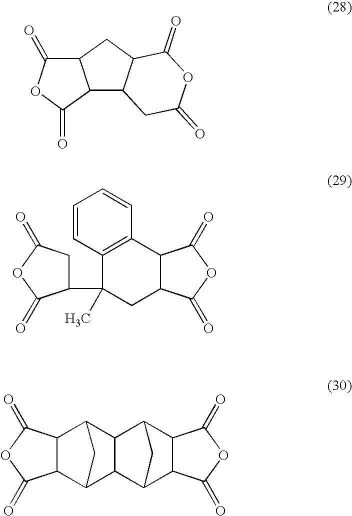 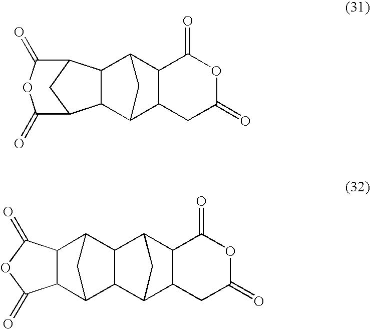 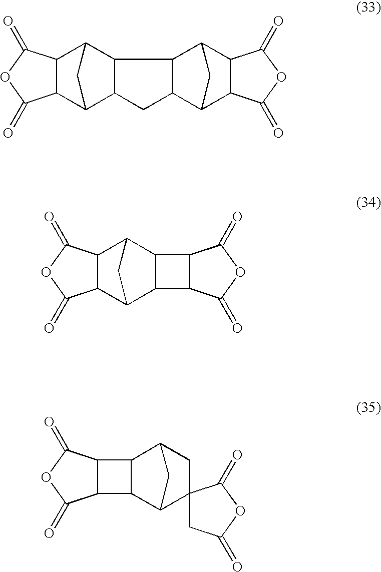 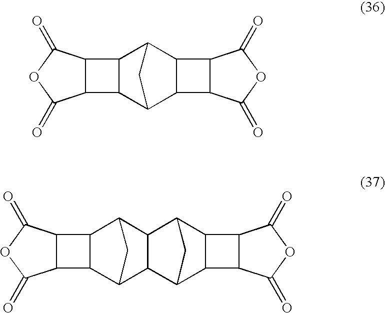 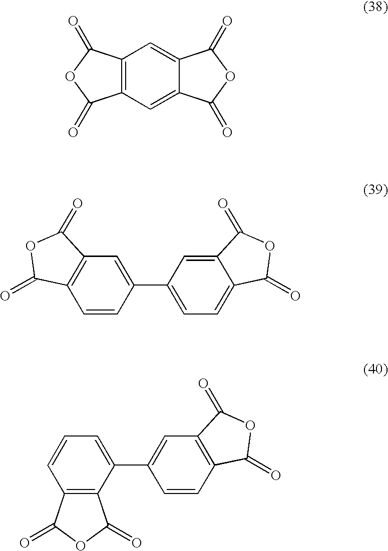 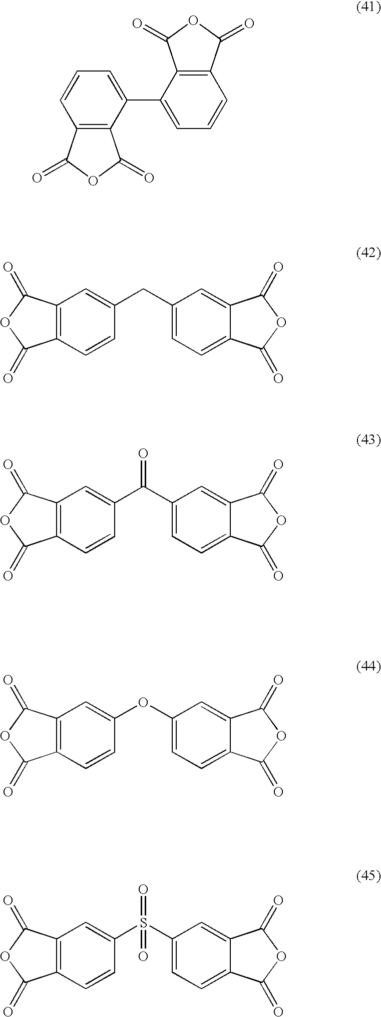 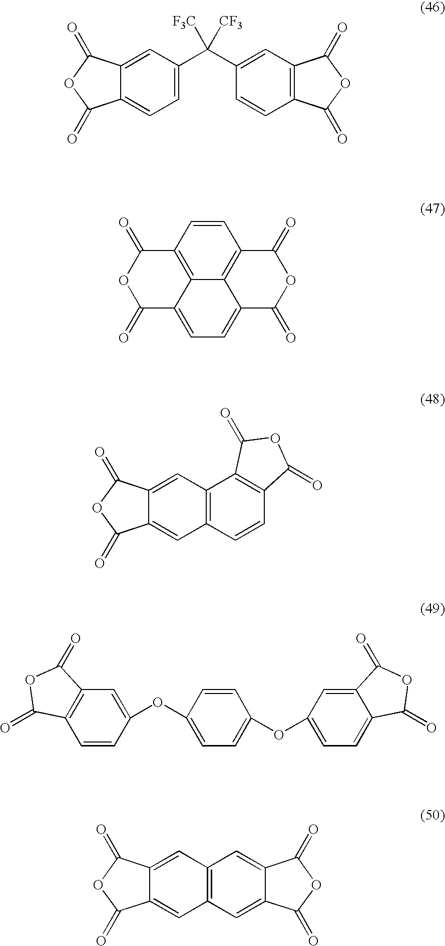
and derivatives thereof, while the diamine compound B contains diamine having a side chain.

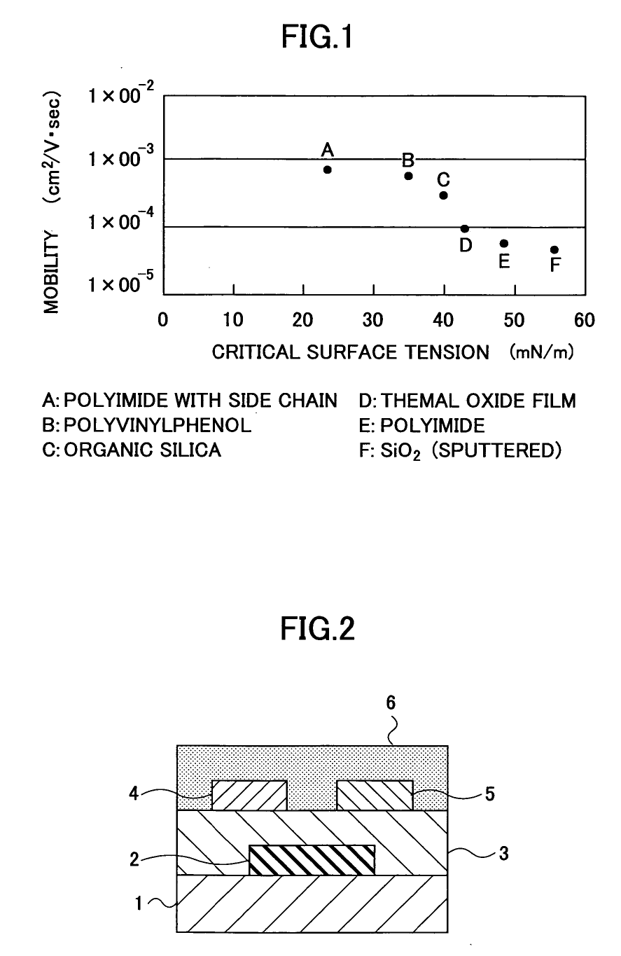

Thus, it becomes possible to form the insulator layer by way of coating process, and the electron device can be fabricated with low cost. Further, it becomes possible to form an insulator layer of good insulating performance, and reliability of the electron device is improved. Further, because of the use of diamine having a side chain, the critical surface tension of the insulator layer is decreased and the semiconductor characteristics are improved. As shown in FIG. 1, there is observed a phenomenon that the mobility of the semiconductor layer is increased when the critical surface tension has decreased below a predetermined value.

Here, it should be noted that the derivative of the polyamic acid and the derivative of the tetracarbonic acid dianhydride are identical as before.

In order to increase the insulating performance of the insulator layer, it is preferable that the component B of the tetracarbonic acid dianhydride compound is at least one of the tetracarbonic anhydrides represented by the structural formulae (1)-(37) or derivatives thereof, wherein it is more preferable that the component B is at least one of the tetracarbonic acid dianhydrides shown in the structural formulae (1)-(7) and (14)-(23) and derivatives thereof. Further, it is more preferable that the component B is at least one of the tetracarbonic acid dianhydrides shown in the structural formulae (1), (6), (7) and (17)-(23) and derivatives thereof.

In the present invention, it should be noted that “diamine having a side chain” means the diamine having a side chain in the case the chain connecting two amino groups are regarded as the principal chain. Thus, the polyamic acid B and the derivative thereof have a side chain. Because the polyamic acid B having a side chain or the derivatives thereof show the tendency of decrease of critical surface tension, it becomes possible to improve the mobility of the semiconductor layer with the use of these substances. Further, it is possible to change the critical surface tension of an insulator layer easily by providing energy such as ultraviolet light.

The side chain of the diamine can be chosen as desired according to the demanded critical surface tension, wherein it is preferable that the side chain contains three or more carbon atoms. While it is not limited, it is preferable to use, for the side chain, any of: a phenyl group or an alkyl group containing three or more carbon atoms, an alkenyl group or an alkynyl group; a phenoxy group or an alkoxy group containing three or more carbon atoms, an alkenyloxy group or an alkynyloxy group; benzoyl group or an acyl group containing three or more carbon atoms, alkenylcarbonyl group or an alkynylcarbonyl group; a benzoyloxy group or an acyloxy group containing three or more carbon atoms, an alkenylcarbonyloxy group or an alkynylcarbonyloxy group; a phenoxycarbonyl group or an alkoxycarbonyl group containing three or more carbon atoms, an alkenyloxycarbonyl group or an alkynyloxycarbonyl group; a phenylaminocarbonyl group or an alkylaminocarbonyl group containing three or more carbon atoms, an alkenylaminocarbonyl group or an alkynylaminocarbonyl group; a cyclic alkylene group containing three or more carbon atoms, and the like.

In the present invention, it is preferable that the diamine having the side chain is one or more compounds selected from the group of the compounds represented by general formulae (I)-(IV) as

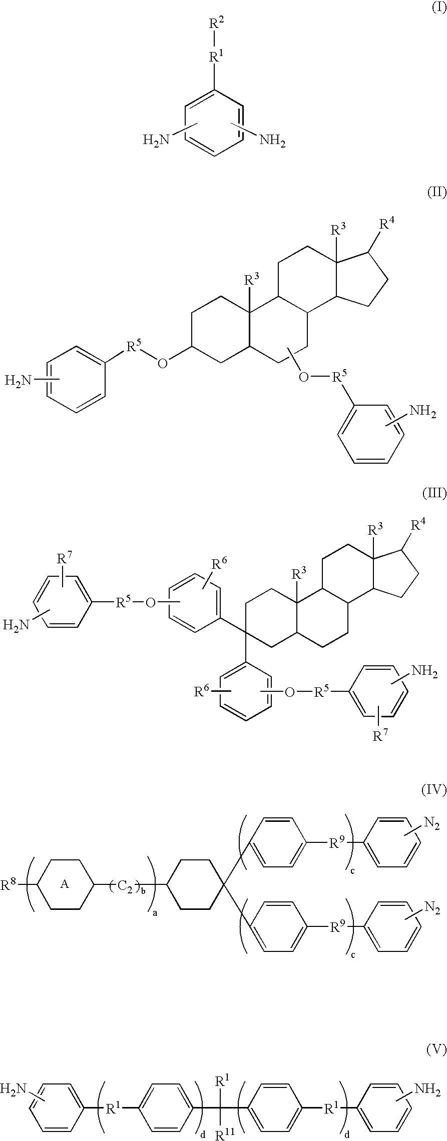

With this, it becomes possible to decrease the critical surface tension OF the insulator layer and improve the mobility of the semiconductor layer.

In the general formula (I), R¹ represents any of a single bond, an oxy group, a carbonyl group, —COO—OCO—, —CONH—, —CH₂O—, —CF₂O— or —(CH₂)e-. Here, e is an integer of one or more but not exceeding six. Further, H in any CH₂ may be replaced with F.

R² is any of the group having a steroid structure, a group represented by a general formula 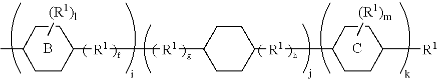
an alkyl group or a phenyl group containing one or more, but not exceeding twenty, carbon atoms.

In the alkyl groups, arbitrary methylene group of the alkyl group containing two or more, but not exceeding six, carbon atoms may be substituted with an oxy group, —CH═CH— or —C≡C—. Further, the hydrogen atom of the phenyl group may be substituted with any of a fluoro group, a methyl group, a methoxy group, a fluoromethoxy group, a difluoromethoxy group or a trifluoromethoxy group.

Further, while the bonding position of the amino groups in the benzene ring is not particularly limited, it is preferable that the two amino groups are in the meta- or para-relationship. Further, it is preferable that the two amino groups are bonded to the third and fifth positions or second and fifth positions, provided that the first position is defined as the position where the R²—R¹— group is bonded.

Further, each of R¹³, R¹⁴ and R¹⁵ is, independently, any of a single bond, an oxy group, —COO—OCO—, —CONH—, an alkylene group containing one or more, but not exceeding four, carbon atoms, an oxyalkylene group containing one or more, but not exceeding three, carbon atoms, or an alkyleneoxy group containing one or more, but not exceeding three, carbon atoms. Each of R¹⁶ and R¹⁷ is, independently, any of a hydrogen atom, a fluoro group or a methyl group. R¹⁸ is any of a hydrogen atom, a fluoro group, a chloro group, a cyano group, an alkyl group containing one or more, but not exceeding twenty, carbon atoms, an alkoxy group containing one or more, but not exceeding twenty, carbon atoms, an alkoxyalkyl group containing two or more, but not exceeding twenty, carbon atoms, a fluoromethyl group, a difluoromethyl group, a trifluoromethyl group, a fluoromethoxy group, a difluoromethoxy group or a trifluoromethoxy group.

In any of the alkyl group, alkoxy group and the alkoxyalkyl group, an arbitrary methylene group therein may be substituted with a difluoromethylene group or a functional group represented by a general formula of

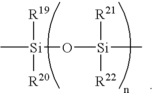

Each of the rings B and C is any of 1,4 phenylene group or 1,4 cyclohexylene group.

Each of f, g and h is independently an integer of zero or more, but not exceeding four, each of i, j and k is independently an integer of zero or more, but not exceeding three, a sum of i, j and k being one or more, each of 1 and m being independently one or two.

Each of R¹⁹ and R²⁰ is any of an alkyl group or a phenyl group having one or more, but not exceeding ten, carbon atoms. Each of R²¹ and R²² is any of an alkyl group or a phenyl group having one or more, but not exceeding ten, carbon atoms, and n is an integer of one or more.

For the diamine resented by the general formula (I), it is possible to use the compounds represented by the formulae (I-1)-(I-39): 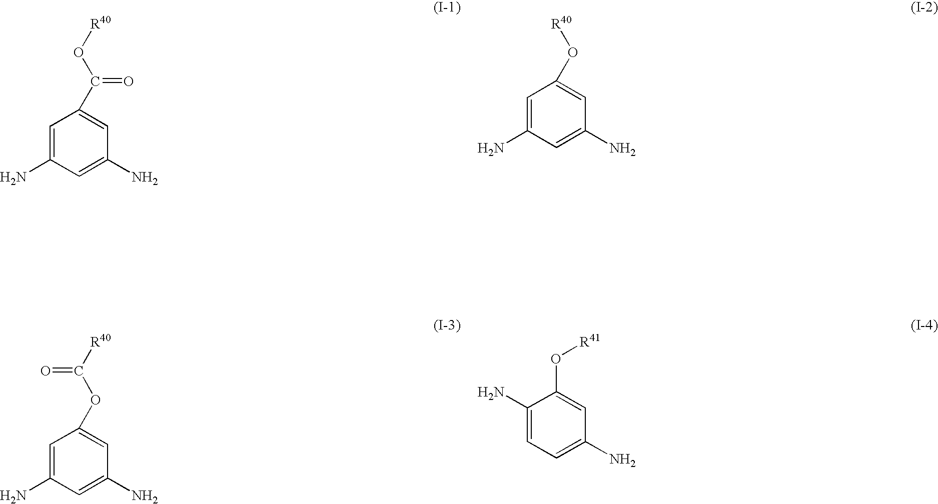 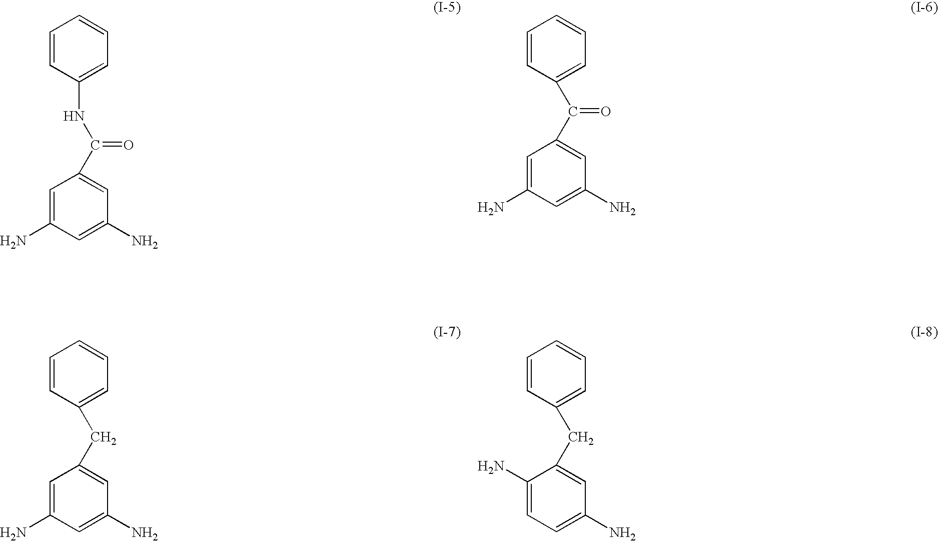 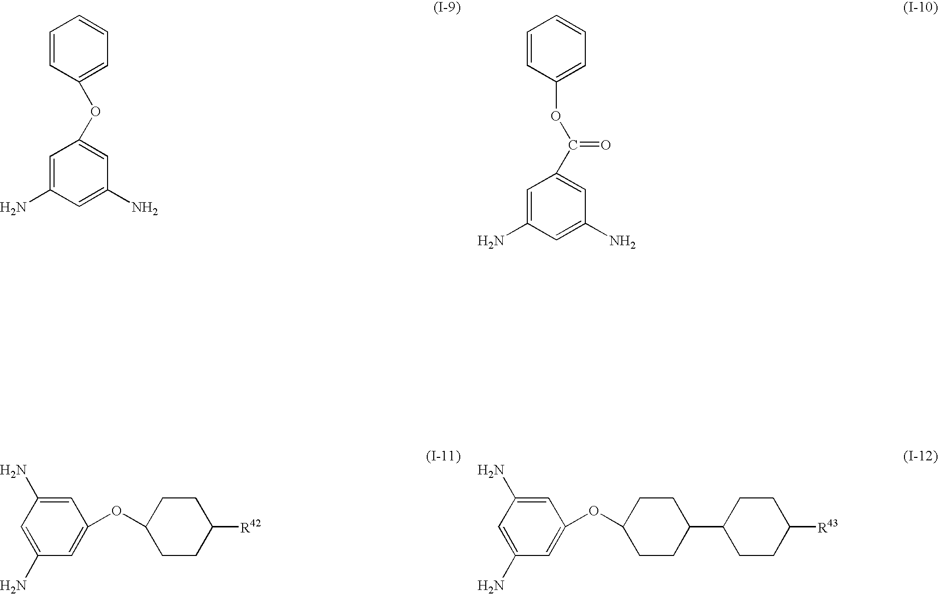 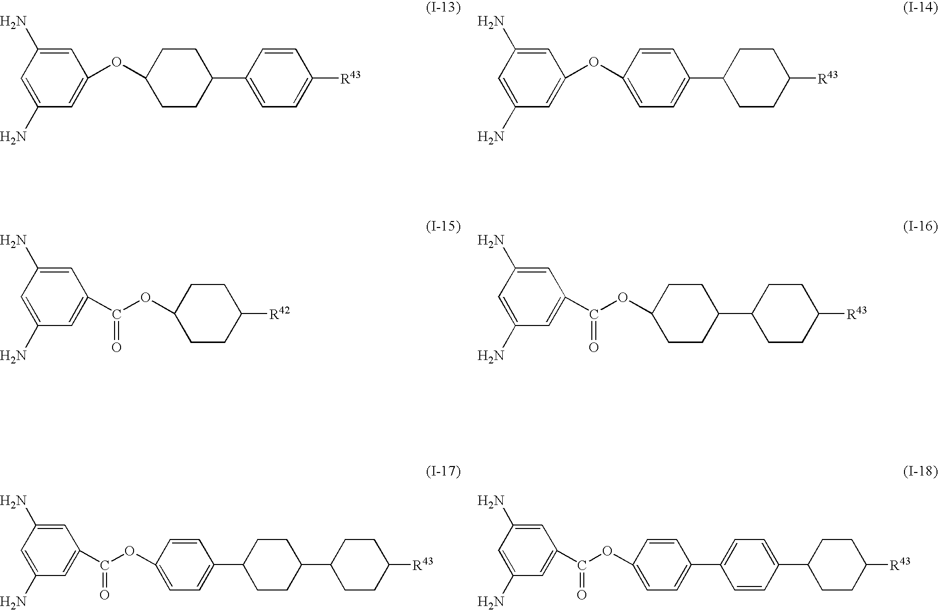 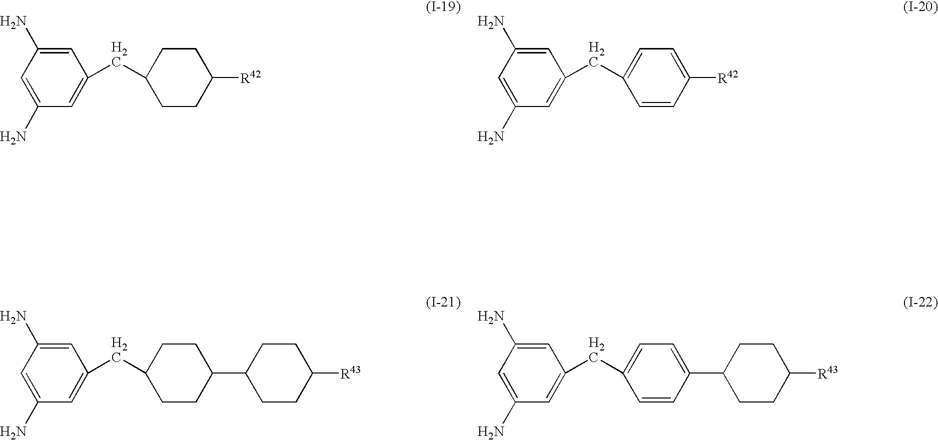 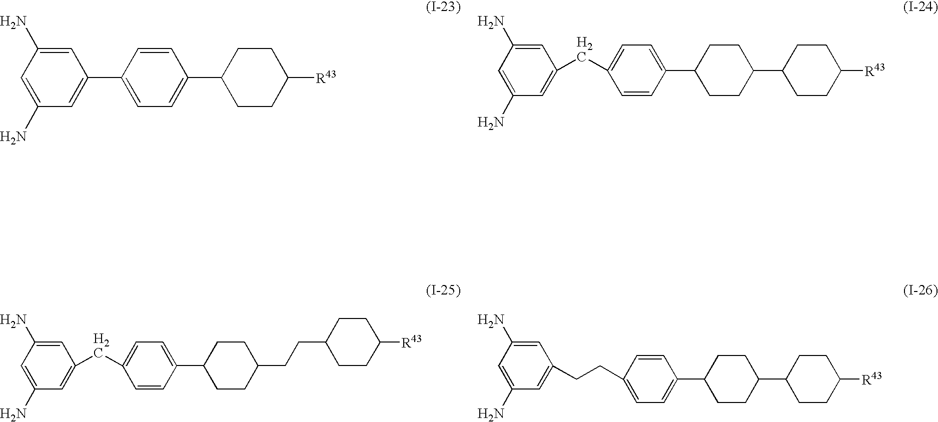 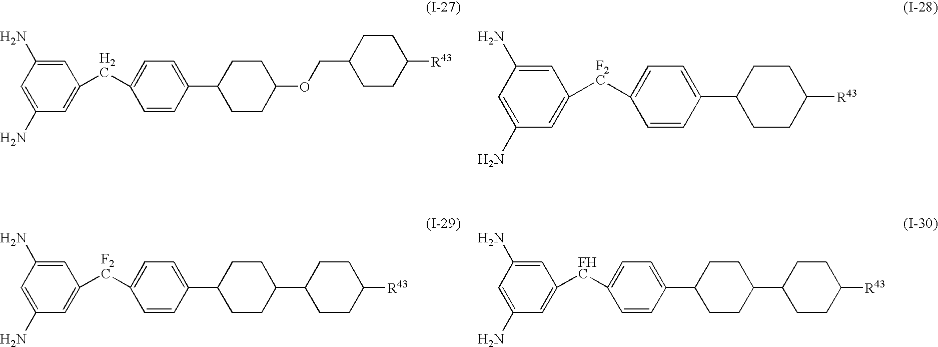 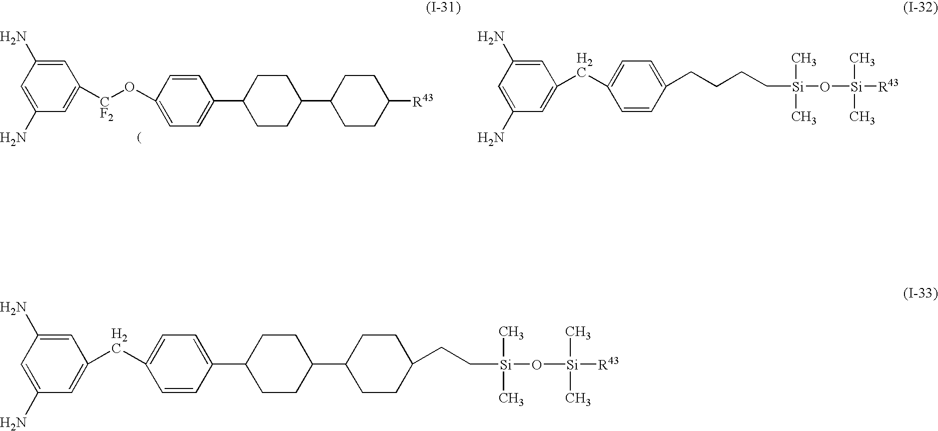 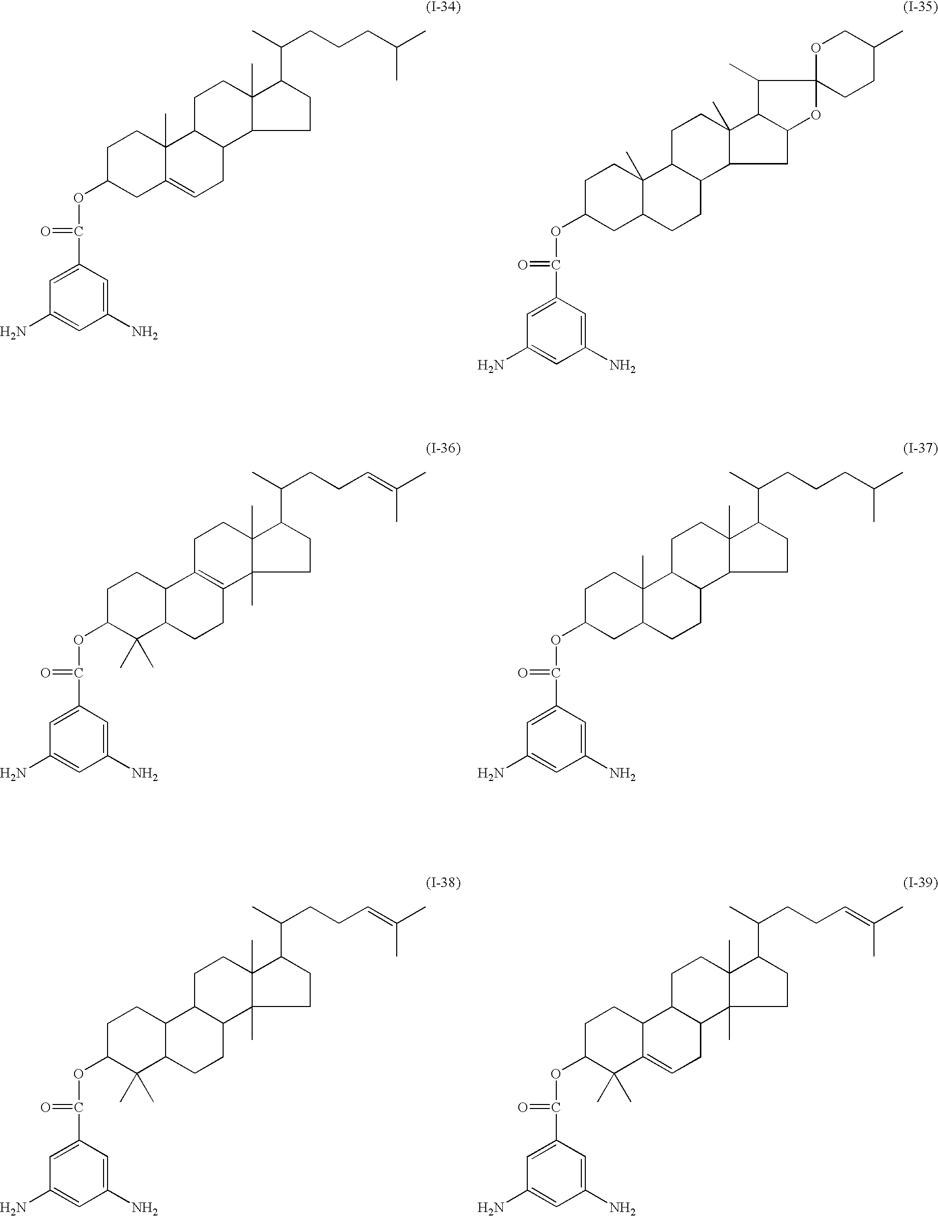
wherein R⁴⁰ is an alkyl group having four or more, but not exceeding twelve, carbon atoms, R⁴¹ is an alkyl group having six or more, but not exceeding twenty, carbon atoms, R⁴² is an alkyl group or an alkoxy group having one or more, but not exceeding ten, carbon atoms, and R⁴³ is hydrogen, or an alkyl group or an alkoxy group having one or more, but not exceeding ten, carbon atoms.

The method of forming the diamines represented by the foregoing formulae is known. For example, the compounds of the formulae (I-2), (I-3) and (I-4) can be formed by the method disclosed in the Japanese Laid-Open Patent Application 5-27244 official gazette, the compounds of the formulae (I-12), (I-14) and (I-16) can be formed by the method disclosed in the Japanese Laid-Open Patent Application 9-278724 official gazette, the compounds of the formulae (I-19), (I-20), (I-21), (I-22), (I-24) and (I-25) can be formed by the method disclosed in the Japanese Laid-Open Patent Application 2002-162630 official gazette, the compounds of the formulae (I-26), (I-27), (I-28), (I-29), (I-30) and (I-31) can be formed by the method disclosed in the Japanese Laid-Open Patent Application 2003-96034 official gazette, the compound of the formula (I-33) can be formed by the method disclosed in the Japanese Laid-Open Patent Application 2003-267982 official gazette, the compounds of the formulae (I-34), (I-35), (I-36), (I-37), (I-38) and (I-39) can be formed by the method disclosed in the Japanese Laid-Open Patent Application 4-281427 official gazette.

In the general formulae (II) and (III), R³ is, independently in each occurrence, any of a hydrogen atom and a methyl group, R⁴ is, independently in each occurrence, any of a hydrogen atom and an alkyl group containing one or more, but not exceeding twenty, carbon atoms, R⁵ is, independently in each occurrence, any of a single bond, a carbonyl group and a methylene group, R⁶ and R⁷ are, independently in each occurrence, any of an alkyl group and a phenyl group containing one or more, but not exceeding twenty, carbon atoms.

In the general formula (II), it is preferable that the NH₂—Ph—R⁵—O— group is bonded to the third position or sixth position of the steroid core. Further, it is preferable that the amino group is bonded at the meta position or para position with regard to the bonding position of R⁵.

For the diamines represented by the general formula (II), it is possible to use the compounds represented by the formulae (II-1)-(II-4):

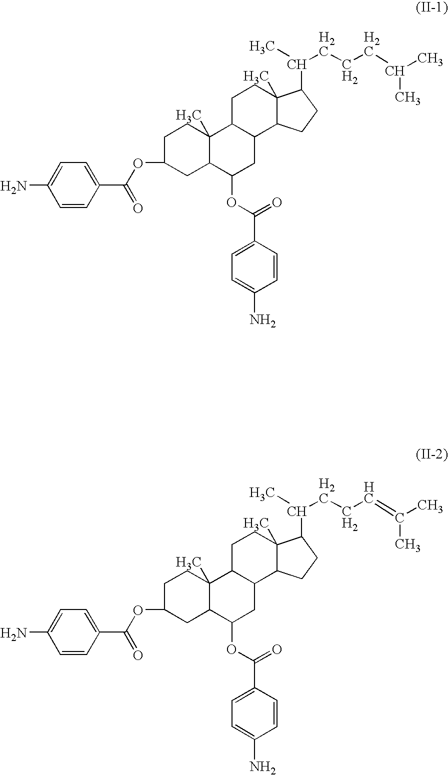

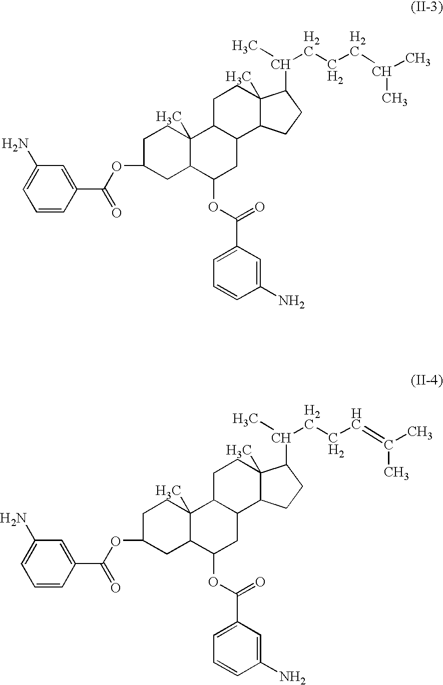

wherein the diamines represented by the formulae (II-1)-(II-4) can be formed by the method disclosed in the Japanese Laid-Open Patent Application 8-269084 official gazette.

In the general formula (III), it is preferable that the group (NH₂)(R⁷)Ph—R⁵—O— is in the meta position or para position with regard to the carbon atom to which the steroid core is bonded. Further, it is preferable that the amino group is in the meta position or para position with regard to R⁵.

For the diamines represented by the general formula (III), it is possible to use the compounds (III-1)-(III-8):

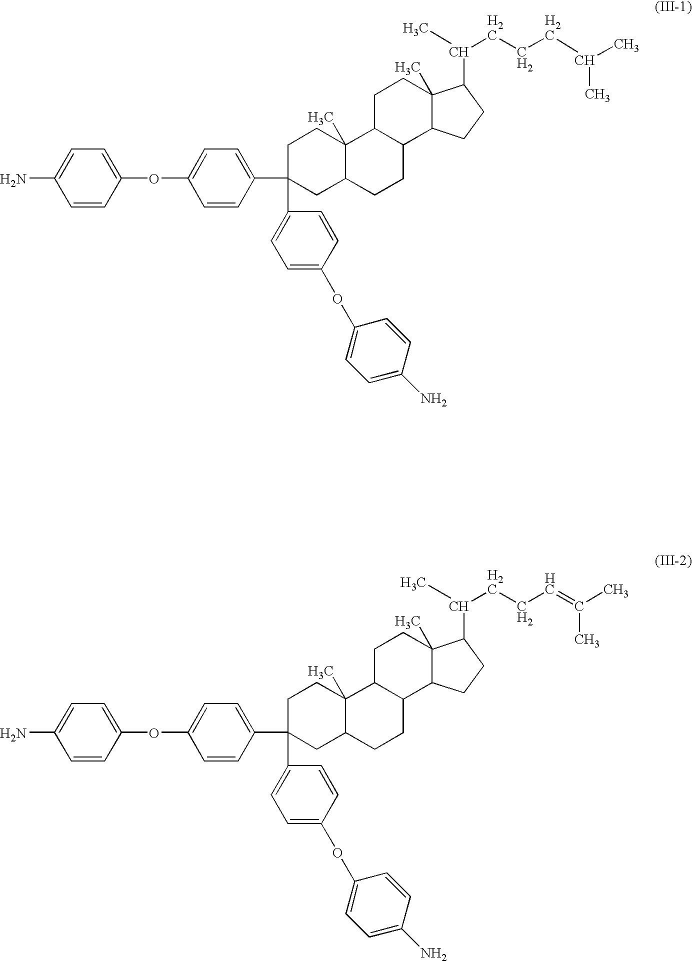

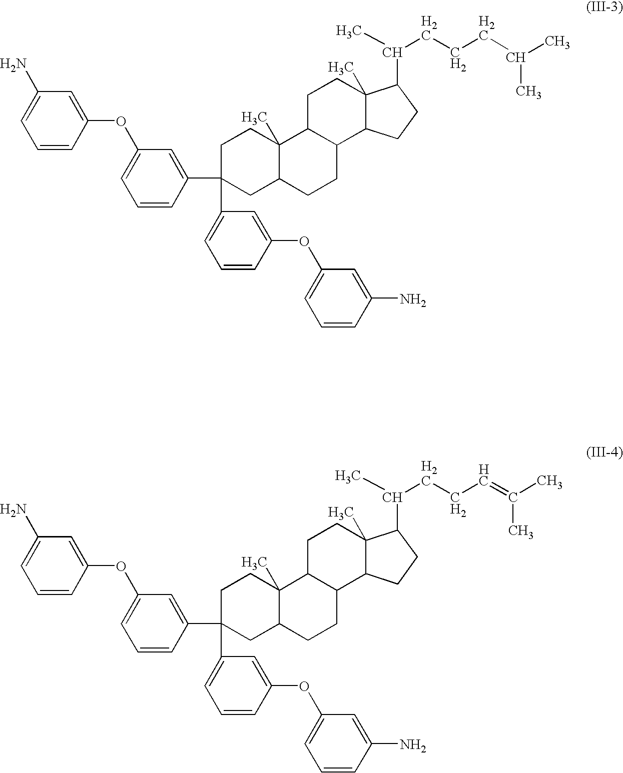

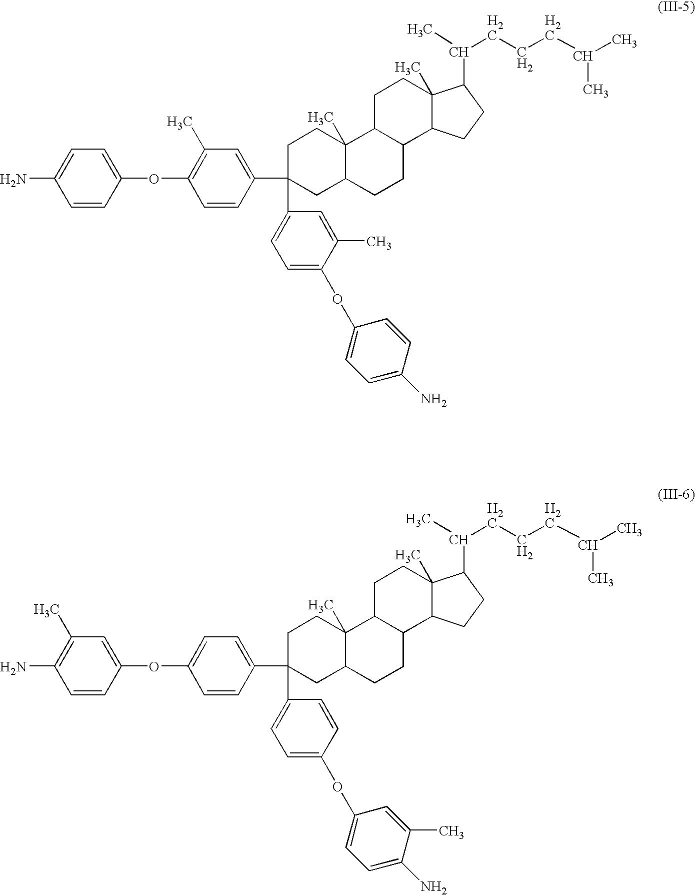

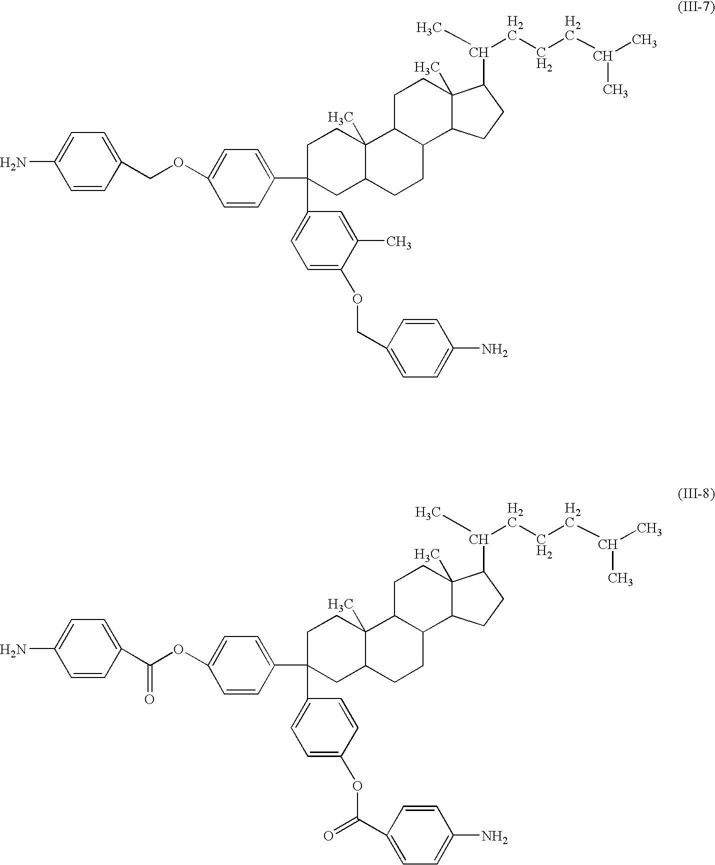

wherein, the diamines represented can be formed by the method disclosed in the Japanese Laid-Open Patent Application 9-143196 official gazette.

In the general formula (IV), R⁸ is a hydrogen atom or an alkyl group containing one or more, but not exceeding twenty, carbon atoms. In the alkyl groups, arbitrary methylene group in the alkyl group containing two or more, but not exceeding twenty, carbon atoms, may be substituted with any of an oxy group, —CH═CH— or —C≡C—. R⁹ is, independently in each occurrence, an oxy group or an alkylene group containing one or more, but not exceeding six. The ring A is a 1,4-phenylene group or 1,4-cylcohexylene group. a is zero or one, b is an integer of zero or larger but not exceeding two, while c is, independently in each occurrence, zero or one.

In the general formula (V), each of R¹⁰ and R¹¹ is any of a hydrogen atom, an alkyl group or a perfluoroalkyl group containing one or more, but not exceeding twenty, carbon atoms, thereby at least one of R¹⁰ and R¹¹ is an alkyl group or a perfluoroalkyl group containing tree or more carbon atoms. R¹² is, independently in each occurrence, an oxy group or an alkylene group containing one or more, but not exceeding six, carbon atoms, while d is zero or one independently in each occurrence.

In the general formula (IV) or (V), the amino group may be in the meta position or para position with regard to R⁹ and R¹², respectively.

The diamines represented by the general formulae (IV) and (V) may be any of the compounds represented by (IV-1)-(IV-6) and (V-1):

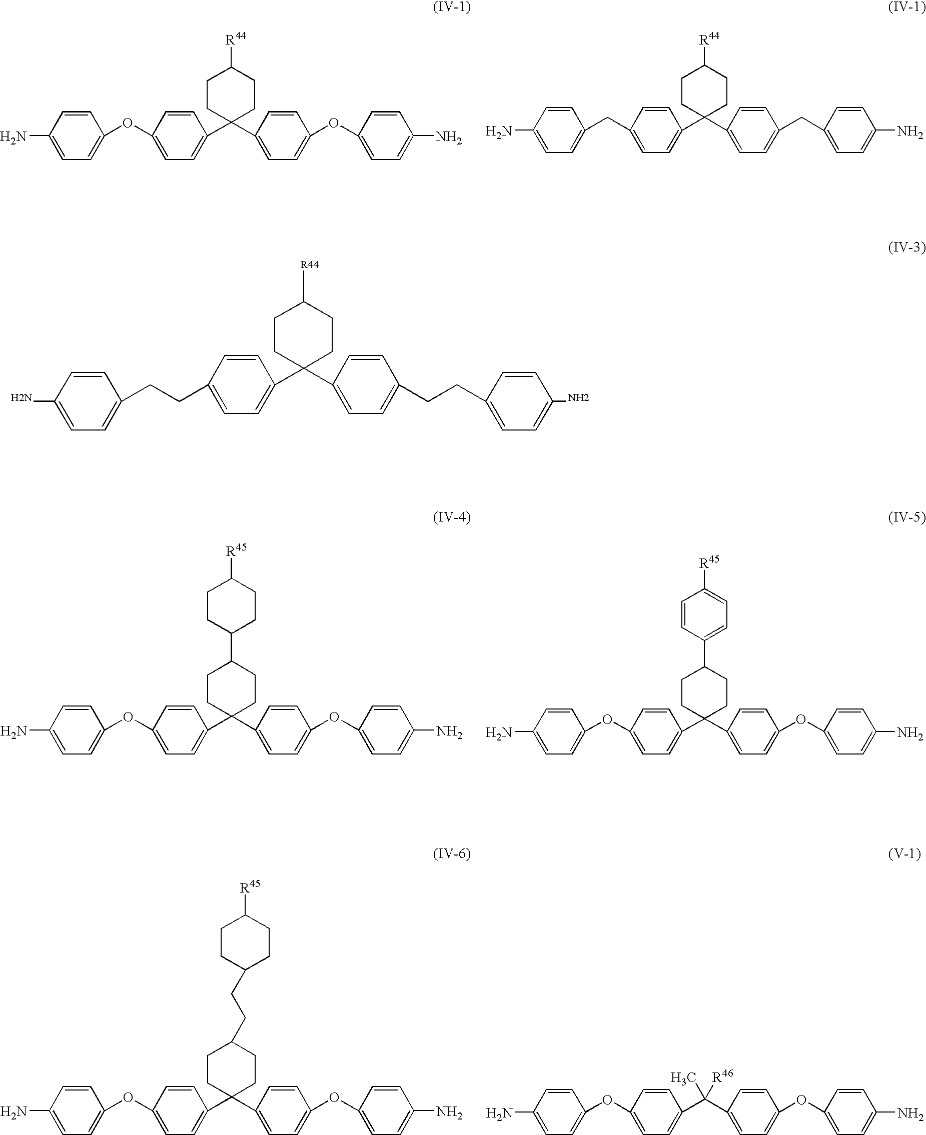

wherein R⁴⁴ is an alkyl group containing one or more, but not exceeding twenty, carbon atoms, R⁴⁵ is an alkyl group or a perfluoroalkyl group containing three or more, but not exceeding ten, carbon atoms.

Thereby, it should be noted that the diamines noted above can be fabricated according to a known method. For example, the compound of the formula (IV-1) can be formed by the method disclosed in the Japanese Laid-Open Patent Application 2-129155 official gazette, the compound of the formula (IV-2) can be formed by the method disclosed in the Japanese Laid-Open Patent Application 6-228061 official gazette, the compounds of the formulae (IV-3) and (IV-4) can be formed by the method disclosed in the Japanese Laid-Open Patent Application 3-167162 official gazette, the compound of the formula (IV-5) can be formed by the method disclosed in the Japanese Laid-Open Patent Application 6-157434 official gazette, the compound of the formula (IV-6) can be formed by the method disclosed in the Japanese Laid-Open Patent Application 3-220162 official gazette, the compound of the formula (V-1) can be formed by the method disclosed in the Japanese Laid-Open Patent Application 1-6246 official gazette,

In the present invention, the diamine compound B can be a single compound or a mixture of two or more compounds. Further, the diamine compound B may contain, in addition to the diamine having the side chain, a compound similar to the diamine compound A.

The mole fraction of the diamine having the side chain with regard to the diamine compound B may be adjusted appropriately in view of the structure of the side chain of the diamine and the desired critical surface tension, wherein it is preferable that the mole fraction is 0.3 or more but not exceeding one, more preferably 0.5 or more but not exceeding 1. With this, the critical surface tension of the insulator layer is decreased and the mobility of the semiconductor layer is increased.

Further, it is possible to add a monoamine in addition to the diamine compound B at the time of the reaction as an end stopper.

In the present invention, the insulator layer may contain both the polyimide material A and the polyimide material B. Thereby, it is preferable that the weight fraction of the polyimide material B to the polyimide material A is in the range of 1-10%, more preferably 5-25%. This weight ratio can be adjusted appropriately in view of the desired critical surface tension and the performance of insulation.

In the present invention, the polyamic acid can be manufactured by using a known process.

For example, diamine is loaded in a reaction vessel equipped with a source inlet, a nitrogen gas inlet, a thermometer, a stirrer and a condenser, together with monoamine if necessary, and thereafter, an amide series polar medium such as N-methyl-2-pyrrolidone, dimethyl formamide, and the like, a tetracarbonic acid dianhydride are added. Thereby, it is possible to add derivatives of the tetracarbonic acid dianhydride according to the needs. Thereby, it is preferably to set the total number of moles of the tetracarbonic acid dianhydride to be 0.9-1.1 times the total number of moles of diamine.

Thereby, a solution of the polyamic acid is obtained by causing a reaction for 1-48 hours at the temperature of 0-70° C. while continue stirring. Thereby, it is also possible to obtain a polyamic acid of low molecular weight by setting the reaction temperature of 50-80° C.

The solution of the polyamic acid thus obtained can be diluted by a solvent for adjusting the viscosity thereof.

Further, it is possible to obtain a soluble polyimide resin as the polyamic acid derivative by imidizing the obtained solution of the polyamic acid together with an acid anhydride used as a dehydrating agent such as an acetic anhydride, a propionic anhydride, a trifluoroacetic acid anhydride, and the like, and a tertiary amine used for a dehydration ring-closure catalyst such as triethylamine, pyridine, collidine, and the like, at the temperature of 20-150° C.

Further, it is possible to add a large amount of poor solvent to the obtained polyamic acid solution to cause precipitation of the polyamic acid, and cause imidization in the precipitated polyamic acid in the solvent of toluene or xylene at the temperature of 20-150° C. similarly as before together with the dehydrating agent and the dehydrating ring-closure catalyst. For the poor solvent, it is possible to use alcohol series solvent such as methanol, ethanol, isopropanol, and the like, or a glycol series solvent.

In the imidization reaction, it is preferable that the mole fraction of the dehydrating ring-closure catalyst to the dehydrating agent is 0.1-10. Further, it is preferable that the total amount of the dehydrating ring-closure catalyst and the dehydrating agent is 1.5-10 times the total number of moles of the tetracarbonic acid dianhydride. The ratio of imidization can be controlled thereby by adjusting the amount of the dehydrating agent and the dehydrating ring-closure catalyst, the temperature and the time of the imidization reaction. The polyimide resin thus obtained may be separated from the solvent and resolving in a solvent to be explained later. Alternatively, the polyimide resin may be used without separating from the solvent.

The polyamic acid ester can be obtained by converting the tetracarbonic acid dianhydride to tetracarbonic acid dialkylester dihalide and causing reaction with thee diamine. Further, by using the tetracarbonic acid dianhydride together with the tetracarbonic acid dialkylester dihalide, it is possible to obtain a polyamic acid ester in which a part of the carbonic acid of the polyamic acid is esterified.

Further, the polyamic acid ester is obtained by reacting alcohol to the polyamic acid. In this case, by controlling the mole fraction of the alcohol or other reaction conditions, it is possible to obtain the polyamic acid ester in which all or a part of the carbonic acid in the polyamic acid is esterified.

As noted above, a part of the tetracarbonic acid dianhydride may be a dicarbonic acid halide. Further, by causing the reaction between the tetracarbonic acid dianhydride compound containing dicarbonic acid halide with a diamine, it is possible to obtain a polyamic acid-polyamide copolymer. Here, the ratio of dicarbonic acid halide with respect to the tetracarbonic acid dianhydride is not specified, as long as the effect of the present invention is not adversary affected.

Further, by imidizing the polyamic acid-polyamide copolymer, it is possible to manufacture a polyamideimide resin. Further, the polyamic acid-polyamide copolymer and the polyamide-imide resin thus obtained can be used by separating from the solvent and further resolving in a solvent as will be described later similar to the case of polyimide. Alternatively, they can be used without being separated from the solvent.

In order to form a film by coating of at least one of the polyamic acid and the derivative thereof in the present invention, it is preferable to use a solution in which at least one of the polyamic acid and the derivative thereof is dissolved. Thereby, the content of one of the polyamic acid and its derivative in the solvent can be chosen appropriately according to the coating process used for the film formation. Thus, in the case of using a printer such as an offset printer, ink-jet printer, and the like (referred to hereinafter as printing machine), it is preferable to set the foregoing content to 0.5-30 weight percent, more preferably 1-15 weight percent. This content can be adjusted appropriately according to the viscosity of the solution.

For the solvent, any of the solvents used commonly in the manufacturing process of polyamic acids, soluble polyimides, polyamic acid esters, polyamic acid-polyamide copolymers, or the resin components of polyamide-imide resins, can be chosen appropriately according to the purposes. For example, it is preferable that the solvent is a mixed solvent of an aprotonic polar solvent, which is a good solvent to at least one of the polyamic acid and its derivative, and another solvent added for the purpose of improving the coating performance, or the like, by changing the surface tension.

For the aprotonic polar solvent, it is possible to use any of N-methyl-2-pyrrolidone, Dimethyl imidazolidinone, N-methyl caprolactam, N-methyl propioneamide, N,N-dimethylacetoamide, dimethyl sulfoxide, N,N-dimethylformamide, N,N-diethylformamide, diethylacetoamide, γ-butyrolactone, γ-valerolactone, and the like, wherein it is preferable to use N-methyl-2-pyrrolidone, dimethyl imidazolidinone, γ-butyrolactone, and γ-valerolactone

For the other solvent, it is possible to use ethyleneglycol monoalkyl ether such as alkyl lactate, 3-methyl-3-methoxybutanol, tetralin, isophorone, ethyleneglycol monobutyl ether, diethyleneglycol monoethyl ether such as diethyleneglycol monoalkyl ether, propyleneglycol monoalkyl ether such as ethyleneglycol monoalkyl (or phenyl) acetate, triethyleneglycol monoalkyl ether, propyleneglycol monoalkyl ether such as propyleneglycol monobutyl ether, dialkyl malonate such as diethyl malonate, dipropyleneglycol monoalkyl ether such as dipropyleneglycol monomethyl ether, and ester compounds of acetate of the foregoing. Particularly, it is preferable to use ethyleneglycol monobutyl ether, diethyleneglycol monoethyl ether, propyleneglycol monobutyl ether, dipropyleneglycol monomethyl ether, and the like.

The composition and proportion of the aprotonic polar solvent and the other solvent can be set appropriately by taking into consideration the printability, coating performance, solubility, stability for storage, and the like. Thereby, it is preferable that the aprotonic polar solvent is good in the solubility and stability for storage, while the other solvent is preferably good in printability and coating.

The solution of at least one of the polyamic acid and its derivative may be added with various additives according to the needs.

In the present invention, it is preferable to use an imidization catalyst as an additive. With this, it becomes possible to obtain the polyimide material by causing the imidization reaction at low temperatures. Thereby, it becomes possible to use various materials for the substrate.

It should be noted that the volume resistivity of the polyimide material increases with increasing degree of imidization, while in order to fabricate an electron device of good characteristics, it is preferable that the gate insulation film has a volume resistivity of 1×10¹² Ωcm or more, more preferably 1×10¹⁴ Ωcm or more. The higher the volume resistivity of the gate insulation film, the smaller the leakage of the gate electrode. Thereby, the power consumption is reduced and the reliability of the electron device is improved.

For the imidization catalyst, it is possible to use: Aliphatic series amines, such as trimethylamine, triethylamine, tripropylamine, tributylamine, and the like; aromatic amines such as N,N-dimethyl aniline, N,N-diethyl aniline, methyl-substituted aniline, hydroxyl-substituted aniline, and the like; cyclic amines such as pyridine, methyl-substituted pyridine, hydroxy-substituted pyridine, quinoline, methyl-substituted quinoline, hydroxy-substituted quinoline, isoquinoline, methyl-substituted isoquinoline, hydroxy-substituted isoquinoline, imidazole, methyl-substituted imidazole, hydroxy-substituted imidazole, and the like. Particularly, it is preferable to use N,N-dimethyl aniline, o-hydroxy aniline, m-hydroxy aniline, p-hydroxy aniline, o-hydroxy pyridine, m-hydroxy pyridine, p-hydroxy pyridine, isoquinoline.

Usually, it is preferable to add the imidization catalyst with 0.01-5 equivalent weight, preferably 0.05-3 equivalent weight with respect to the carbonic group of the polyamic acid and its derivative.

In the present invention, it is possible to use surfactant as the additive. Thereby, the coating performance is improved. Further, it is also possible to add antistatic agent. With this, the antistatic performance of the insulator layer is improved.

Further, in order to improve the adherence to the substrate, it is possible to add a silane coupling agent or titanium series coupling agent.

For the silane coupling agent, it is possible to use vinyl trimethoxy silane, vinyl triethoxy silane, N-(2-aminoethyl)-3-aminopropyl metyldimethoxy silane, N-(2-aminoethyl)-3-aminopropyl methyl trimethoxy silane, p-aminophenyl trimethoxysilane, P-aminophenyl triethoxysilane, M-aminophenyl trimethoxysilane, M-aminophenyl triethoxysilane, 3-aminopropyl trimethoxysilane, 3-aminopropyl triethoxysilane, (3-glycidoxypropyl)trimethoxysilane, (3-glycidoxypropyl)methyldimethoxysilane, 2-(3,4-epoxycyclohexyl)ethyl trimethoxysilane, 3-chloropropyl methyldimethoxysilane, 3-chloropropyl trimethoxysilane, 3-metacryloxypropyl trimethoxysilane, 3-mercaptopropyl trimethoxysilane, N-(1,3-dimethylbutylidene)-3-(triethoxysilyl)-1-propyl amine, N,N′-bis[3-(trimethoxysilyl) propyl]ethylenediamine, and the like.

Usually, the silane coupling material is added with a proportion of 0-10%, preferably 0.1-3%, with regard to the total weight of the polyamic acid and the derivatives. Other additives are added usually in proportion of 0-30%, preferably 0.1-10%, with regard to the total weight of the polyamic acid and its derivatives.

The solution containing at least one of the polyamic acid and the derivatives thereof may be applied by various processes including a spinner process, printing process, dripping process, ink-jet process, or the like.

After coating of the solution containing at least one of the polyamic acid and the derivatives thereof, the film thus obtained is dried, and by further applying heating processing necessary for the dehydration and ring-closure reaction of the polyamic acid and the derivatives thereof to the film, an insulator layer containing the desired polyimide material is obtained.

The drying and heating processing may be conducted by using an oven, infrared furnace, hotplate, or the like. Thereby, it is preferable to conduct the drying process at a relatively low temperature such as 50-100° C. in which evaporation of the solvent is possible. Further, the heating reaction is conducted preferably at the temperate of 150-300° C.

The viscosity of the foregoing solution of at least one of the polyamic acid and the derivatives thereof is chosen according to the coating process used, and can be controlled by way of the structure and concentration of one of the polyamic acid and the derivatives thereof or by choosing the solvent. For example, it is preferable that the viscosity of the solution is 5-100 mPa·second, preferably 10-80 Pa·second when applying by a printing apparatus. When using the printing apparatus, it becomes difficult to obtain sufficient film thickness when the viscosity of the solution is smaller than 5 mPa·second. On the other hand, when the viscosity exceeds 100 mPa·second, there is a case that non-uniform print may be caused.

In the case of applying the solution by a spin-coating process, it is preferable to set the viscosity of the solution to 5-200 mPa·second, more preferably 10-100 mPa·second.

In the present invention, it is preferable that the semiconductor layer is formed of an organic semiconductor material.

Generally, an organic insulator material can be used to form a film at a temperature of about 100° C. by way of evaporation deposition or coating in the form of a solution in which the organic semiconductor material is dissolved in a solvent. Thus, as compared with the case of inorganic semiconductor materials such as silicon, it is possible to form the semiconductor layer at low temperatures with the use of the organic semiconductor material, and it becomes possible to use a wide variety of materials for the substrate. Particularly, it becomes possible to reduce the thickness and weight of the apparatus by using a resin film for the substrate. Further, in the case of forming the film by coating, it becomes possible to significantly reduce the cost of the facilities used for the device fabrication as compared with the case of fabricating inorganic semiconductor devices.

For the organic semiconductor material, it becomes possible to use one or more materials selected from the group consisting of: fluorene, polyfluorene derivatives, polyfluorenone, fluorenone derivatives, poly N-vinylcarbazole derivatives, poly γ-carbazolyl ethylglutamate derivatives, polyvinyl phenanthrene derivatives, polysilane derivatives, oxazole derivatives, oxadiazole derivatives, imidazole derivatives, monoarylamine, arylamine derivatives such as triarylamine derivative, bennzidine derivatives, diarielmethane derivatives, triarielmethane derivatives, styrylanthracene derivatives, pyrazoline derivatives, divinylbenzene derivatives, hydrazone derivatives, indene derivatives, indenone derivatives, butadiene derivatives, pyrene-formaldehyde, pyrene derivatives such as polyvinylpyrene, stilbene derivatives such as α-phenylstilbene derivative and bis-stilbene derivative, enamine derivatives, and thiophene derivatives such as polyalkylthiophene, or one ore more materials selected from the group consisting of: pentacene, tetracene, bisazo, trisazo series dye, polyazo series dye, triarielmethane series dye thiazine series dye, oxazine series dye, xanthene series dye, cyanine series dye, styryl series dye, pyrylium series dye, quinaclidone series dye, indigo series dye, perylene series dye, polycyclic quinone series dye, bisbenzimidazole series dye, indanthrone series dye, squalirium series dye, anthraquinone series dye, copper phthalocyanine, and phthalocyanine series dye such as titanylphthalocyanine.

FIG. 2 shows an example of the electron device of the present invention.

Referring to FIG. 2, there are laminated consecutively a gate electrode 2 (first electrode layer), an insulator layer 3, a second electrode layer of a source electrode 4 and a drain electrode 6 and a semiconductor layer 6 on a substrate 1.

Thereby, it should be noted that the source electrode 4 and the drain electrode e5 are formed on the region of the insulator layer 3 where energy is provided and has a relatively higher critical surface tension as compared with the region in which no energy is provided. Thereby, it becomes possible to form these electrodes by a coating process, and it becomes possible to reduce the process time as compared with miniaturized patterning process such as photolithographic process.

The insulator layer 3 is formed of two or more polyimide materials selected from the group consisting of the polyimide material A and the polyimide material B, and it is preferable that there is formed a concentration profile of the polyimide material in the thickness direction thereof. With this, it becomes possible to decrease the critical surface tension of the insulator layer 3 in the case there is a high concentration of the material of the small critical surface tension on the surface part of the insulator layer 3 as compared with the case in which there is a uniform concentration profile.

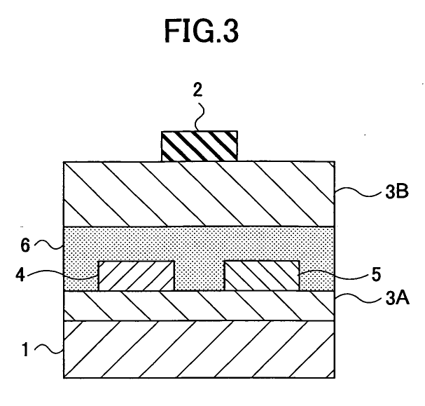

FIG. 3 shows another example of the electron device of the present invention.

Referring to FIG. 3, there are laminated consecutively an insulator layer 3A (first insulator layer), source and drain electrodes 4 and 5 (first electrode layer), a semiconductor layer, an insulator layer 3B (second insulator layer) and a gate electrode 2 (second electrode layer) on a substrate 1.

Thereby, it should be noted that the source electrode 4 and the drain electrode 5 are formed on the region of the insulator layer 3A where energy is provided and has a relatively higher critical surface tension as compared with the region in which no energy is provided. Thereby, it becomes possible to form these electrodes by a coating process, and it becomes possible to reduce the process time as compared with miniaturized patterning process such as photolithographic process.

The insulator layer 3A is formed of two or more polyimide materials selected from the group consisting of the polyimide material A and the polyimide material B, and it is preferable that there is formed a concentration profile of the polyimide material in the thickness direction thereof. With this, it becomes possible to decrease the critical surface tension of the insulator layer 3A in the case there is a high concentration of the material of the small critical surface tension on the surface part of the insulator layer 3A as compared with the case in which there is a uniform concentration profile.

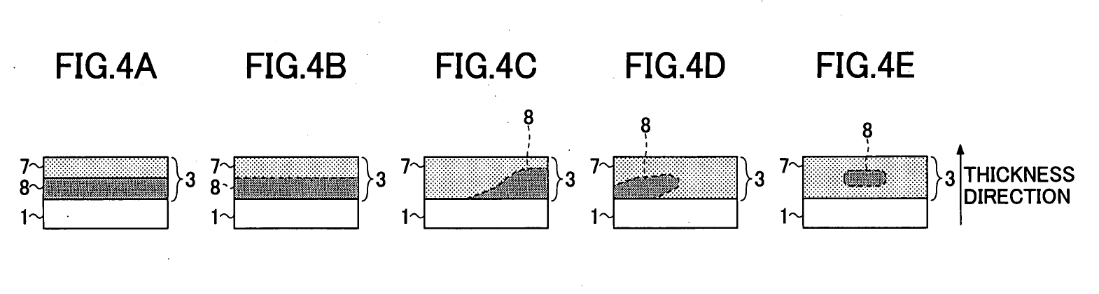

FIGS. 4A-4E show various thickness concentration profiles in the insulator layer 3 or 3A.

It should be noted that the structure of FIGS. 4A and 4B can be obtained by the process of applying a solution in which a first polyimide material 7 of small critical surface tension is mixed with a second polyimide material 8 to form a film after drying. Thereby, the first polyimide material 7 is caused to migrate to the surface side during the drying step conducted for evaporating the solvent, by reducing the polarity of the first polyimide material 7 with regard to the polarity of the second polyimide material, or by reducing the molecular weight of the first polyimide material 7 with regard to the molecular weight of the second polyimide material 8.

In the case of using a coating process, it is frequently the case in which the first polyimide material 7 and the second polyimide material 8 do not cause phase separation as represented in FIG. 4B. Even in such a case, the present invention is applicable when the concentration of the first polyimide material 7 is larger than the concentration of the second polyimide material 8 at the outermost surface of the insulator layer 3.

Further, as indicated in FIGS. 4C-4E, it is possible that the first polyimide material and the second polyimide material 8 are mixed with a predetermined concentration profile in the thickness direction of the insulator film 3.

Further, it is possible that the solution is formed by three or more materials and the insulator layer 3 may have a lamination structure of three or more layers. Further, it is possible that the materials are mixed without forming layers but with a predetermined concentration profile in the thickness direction.

In the present invention, it is possible to apply energy to minute regions of the insulator layer. Such energy is preferably provided in the form of ultraviolet light. Thereby, it is preferable to use a relatively short wavelength ultraviolet radiation of the wavelength of 300 nm or less but not shorter than 100 nm. It should be noted that the ultraviolet radiation of this wavelength range is absorbed by the polyimide material in the insulator layer.

Further, it is preferable that at least one of the first electrode layer and the second electrode layer is formed by an ink-jet process. By doing so, it becomes possible to form minute patterns as compared with coating processes such as dipping process, spin coating process, spray coating process, and the like.

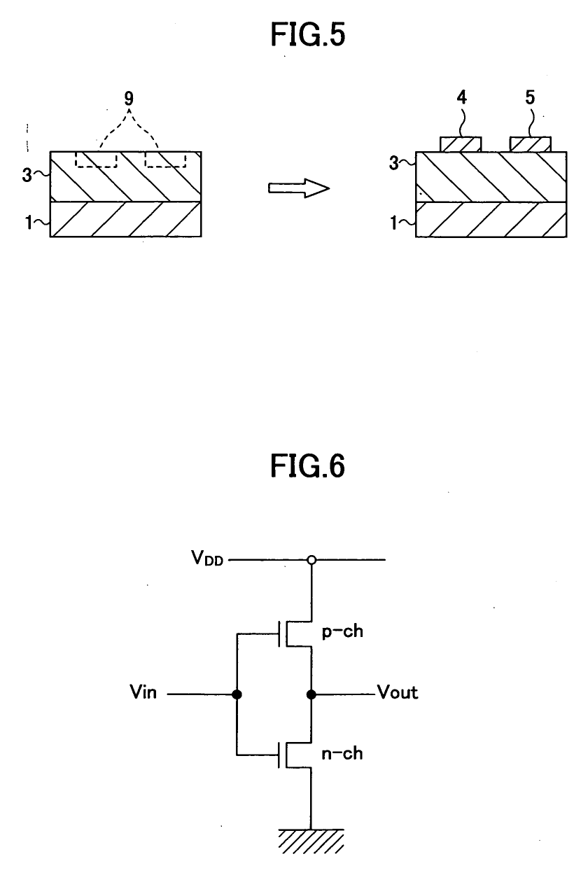

FIG. 5 shows an example of patterning of the electrode of the present invention.

In the example of FIG. 5, the source electrode 4 and the drain electrode 5 are formed on the regions 9 where the ultraviolet irradiation has been made. In forming such electrodes 4 and 5, there is a need of suppressing occurrence of short circuit in view of the reduced inter-electrode distance with miniaturization of the electrode interconnection patterns.

By using the ink-jet process, it becomes possible provide the electrode material selectively to the regions 9 where the ultraviolet irradiation has been made, and it becomes possible to provide a highly reliable process for fabricating miniaturized electron devices.

For the electrode material, it is possible to use any of metals or alloys or oxides of chromium, tantalum, titanium, copper, aluminum, molybdenum, tungsten, nickel, gold, palladium, platinum, silver, tin, indium, and the like, in the form of nano particles. The nano particles thus formed are dispersed in a solvent and the solvent is used to form a film of the electrodes. Alternatively, it is possible to form a metal alkoxide solution and form a film by a sol-gel process. Further, it is possible to use a coating solution formed by dispersing or dissolving, into a solvent, one or more conductive polymers selected from the group of ionic conductive polymers of: polyacetylene series conductive polymers, polyphenylene series conductive polymers such as polyparaphenylene and its derivatives, polyphenylenevinylene and its derivatives, heterocyclic conductive polymers such as polypyrrole and its derivatives, polythiophene, polyethylenedioxy thiophene and its derivatives, polyfuran and its derivatives, an ionic conductive polymer such as polyaniline and its derivatives. These conductive polymers may be doped with suitable dopant. For the dopant, it is possible to use materials of low vapor pressure such as polysulfonic acid, polystyrene sulfonic acid, naphthalene sulfonic acid, alkylnaphthalene sulfonic acid.

Further, it is possible to form nano particles of conductive carbon and disperse the nano carbon particles in a solvent to form a coating solution for film formation.

FIG. 6 is an example of the circuit that uses the operational device of the present invention, wherein “p-ch” and “n-ch” therein represent respectively the transistors that use a hole-transporting material and an electron-transporting material. The illustrated example functions as a NOT operation circuit when a supply voltage Vpp of +5V is supplied.

More specifically, the transistor p-ch does not cause operation when Viₙ is +5V because of the zero voltage difference between the source and gate regions thereof, while the transistor n-ch causes operation because of supply of the voltage of +5V to the source region thereof. Thereby, the output terminal Vout is grounded at the source side and 0V output is obtained.

When Vin is 0V, on the other hand, the transistor n-ch does not cause operation, while the transistor p-ch causes operation in view of the gate potential of −5V with respect to the source thereof. Thereby, an output voltage of +5V is obtained at the output terminal Vout in correspondence to the supply voltage Vpp.

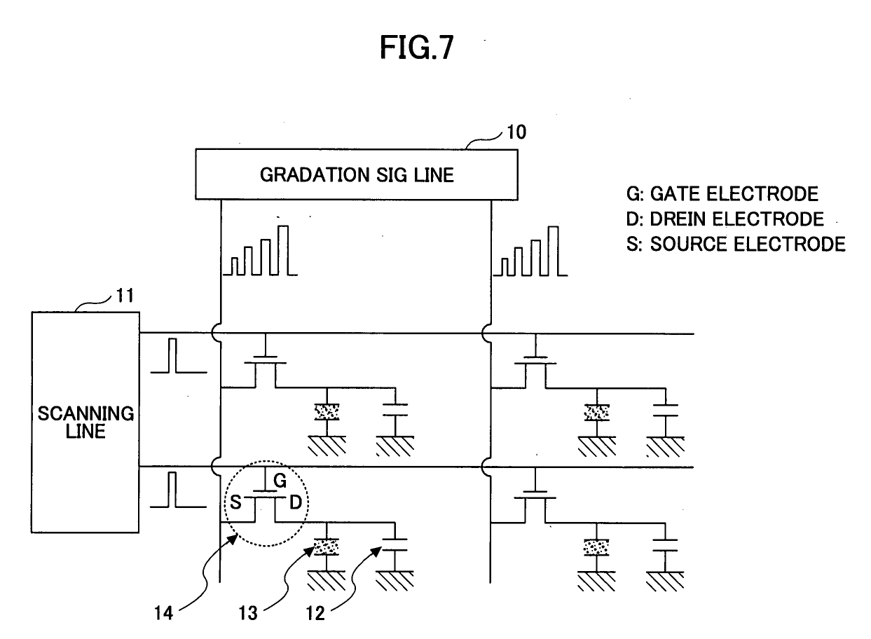

FIG. 7 shows an example of the wiring that uses a display device of the present invention.

Referring to FIG. 7 a voltage is provided to a gradation signal line 10 according to the gradation of respective picture elements.

From the scanning line 11, there are supplied ON/OFF signal voltages line sequentially, and scanning of next frame is started after completion of scanning of the current frame.

In the case of displaying motion pictures, this frame interval is preferably set to be 1/50 seconds or less (50 Hz or higher in terms of frequency). The capacitor 12 is charged with the voltage signal in the transient period from one frame the next frame.

### EXAMPLES

Hereinafter, the present invention is explained by examples and comparative examples, while it should be noted that the present invention is by no means limited to these examples. In the explanation of the examples and comparative examples below, the tetracarbonic dianhydrides, diamines and the solvents may be designated by abbreviation below.

[Tetracarbonic Acid Dianhydride]

1,2,3,4-cyclobutane tetracarbonic acid dianhydride (structural formula (1)): CBDA

1,2,4,5-cyclohexane tetracarbonic acid dianhydride (structural formula (7)): CHDA

pyromeritic acid dianhydride (structural formula (28)): PMDA

[Diamines]

4,4′-diaminodiphenyl methane (structural formula (51)): DDM

2,2-bis[4-(4-aminophenoxy)phenyl] propane (structural formula (83)): BAPP

5-4-[2-(4-n-pentylcyclohexyl)ethyl]cyclohexyl phenylmethyl-1,3-diaminobenzene (structural formula (I-25); R⁴³═C₇H₁₅): 7Ch2Ch

[Solvent]

N-methyl-2-pyrrolidone: NMP

butylcellosolve(ethyleneglycol mono butyl ether): BC

<Synthesis of Polyamic Acid>

[Synthesis 1]

DDM 2.9831 g (15 mmol) and dehydrated NMP 60.0 g are loaded in a four neck flask of 100 ml capacity equipped with a thermometer, a stirrer, a material loading inlet and a nitrogen gas inlet, and dissolved by stirring while causing to flow a dry nitrogen gas.

Next, CBDA 2.360 g (12.0 mmol) and PMDA 0.6563 g (3.0 mmol) are added and reaction was made under room temperature environment for 30 hours. When there is caused an increase of temperature during the reaction, the reaction temperature was controlled not to exceed 70° C.

Further, by adding BC 34.0 g to the solution thus obtained, a solution PA1 of the polyamic acid A of 6 wt % concentration was obtained. The viscosity of PA1 was 42.5 mPa·s.

[Synthesis 2]

DDM 2.9128 g (14.7 mmol) and dehydrated NMP 60.0 g are loaded in a four neck flask of 100 ml capacity equipped with a thermometer, a stirrer, a material loading inlet and a nitrogen gas inlet, and dissolved by stirring while causing to flow a dry nitrogen gas.

Next, CHDA 1.6466 g (7.35 mmol) and CBDA 1.4406 g (7.35 mmol) are added and reaction was made under room temperature environment for 30 hours. When there is caused an increase of temperature during the reaction, the reaction temperature was controlled not to exceed 70° C.

Further, by adding BC 34.0 g to the solution thus obtained, a solution PA2 of the polyamic acid A of 6 wt % concentration was obtained. The viscosity of PA1 was 45.0 mPa·s.

[Synthesis 3]

7Ch2Ch 4.1747 g (8.50 mmol) and dehydrated NMP 60.0 g are loaded in a four neck flask of 100 ml capacity equipped with a thermometer, a stirrer, a material loading inlet and a nitrogen gas inlet, and dissolved by stirring while causing to flow a dry nitrogen gas.

Next, CBDA 0.3350 g (1.70 mmol) and PMDA 1.4903 g (6.80 mmol) are added and reaction was made under room temperature environment for 30 hours. When there is caused an increase of temperature during the reaction, the reaction temperature was controlled not to exceed 70° C.

Further, by adding BC 34.0 g to the solution thus obtained, a solution PA3 of the polyamic acid A of 6 wt % concentration was obtained. The viscosity of PA3 was 12.3 mPa·s.

[Synthesis 4]

DDM 0.5800 g (2.925 mmol), 7Ch2Ch 3.3362 g (6.825 mmol) and dehydrated NMP 60.0 g are loaded in a four neck flask of 100 ml capacity equipped with a thermometer, a stirrer, a material loading inlet and a nitrogen gas inlet, and dissolved by stirring while causing to flow a dry nitrogen gas.

Next, CBDA 0.824 g (1.95 mmol) and PMDA 1.7014 g (7.80 mmol) are added and reaction was made under room temperature environment for 30 hours. When there is caused an increase of temperature during the reaction, the reaction temperature was controlled not to exceed 70° C.

Further, by adding BC 34.0 g to the solution thus obtained, a solution PA4 of the polyamic acid A of 6 wt % concentration was obtained. The viscosity of PA4 was 15.8 mPa·s.

[Synthesis 5]

7Ch2Ch 4.2820 g (8.76 mmol) and dehydrated NMP 60.0 g are loaded in a four neck flask of 100 ml capacity equipped with a thermometer, a stirrer, a material loading inlet and a nitrogen gas inlet, and dissolved by stirring while causing to flow a dry nitrogen gas.

Next, CBDA 1.7180 g (8.76 mmol) is added and reaction was made under room temperature environment for 30 hours. When there is caused an increase of temperature during the reaction, the reaction temperature was controlled not to exceed 70° C.

Further, by adding BC 34.0 g to the solution thus obtained, a solution PA5 of the polyamic acid A of 6 wt % concentration was obtained. The viscosity of PA5 was 15.8 mPa·s.

### Comparative Synthesis Example 1

DDM 2.8570 g (14.41 mmol) and dehydrated NMP 60.0 g are loaded in a four neck flask of 100 ml capacity equipped with a thermometer, a stirrer, a material loading inlet and a nitrogen gas inlet, and dissolved by stirring while causing to flow a dry nitrogen gas.

Next, PMDA 3.143 g (14.41 mmol) is added and reaction was made under room temperature environment for 30 hours. When there is caused an increase of temperature during the reaction, the reaction temperature was controlled not to exceed 70° C.

Further, by adding BC 34.0 g to the solution thus obtained, a solution PA6 of the polyamic acid A of 6 wt % concentration was obtained. In this case, precipitation of the polyamic acid was observed after two days.

### Comparative Synthesis Example 2

BAPP 3.9181 g (9.544 mmol) and dehydrated NMP 60.0 g are loaded in a four neck flask of 100 ml capacity equipped with a thermometer, a stirrer, a material loading inlet and a nitrogen gas inlet, and dissolved by stirring while causing to flow a dry nitrogen gas.

Next, PMDA 2.0819 g (9.544 mmol) is added and reaction was made under room temperature environment for 30 hours. When there is caused an increase of temperature during the reaction, the reaction temperature was controlled not to exceed 70° C.

Further, by adding BC 34.0 g to the solution thus obtained, a solution PA7 of the polyamic acid A of 6 wt % concentration was obtained. In this case, the viscosity of the obtained solution PA7 was 48.9 mPa·s.

### Example 1

A mixed solution S1 containing PA1 95 g and PA3 5 g was spin-coated and baked at 280° C. for one hour in a glove box. With this a polyimide film having a thickness of about 200 nm was obtained.

### Example 2

A mixed solution S2 containing PA1 95 g and PA4 5 g was spin-coated and baked at 280° C. for one hour in a glove box. With this a polyimide film having a thickness of about 200 nm was obtained.

### Example 3

A mixed solution S3 of PA2 100 g was spin-coated and baked at 280° C. for one hour in a glove box. With this a polyimide film having a thickness of about 200 nm was obtained.

### Example 4

A mixed solution S4 containing PA2 95 g and PA5 5 g was spin-coated and baked at 280° C. for one hour in a glove box. With this a polyimide film having a thickness of about 200 nm was obtained.

### Example 5

A mixed solution S5 containing PA1 95 g and PA5 5 g and p-hydroxy pyridine (imidization catalyst) was spin-coated and baked at 280° C. for one hour in a glove box. With this a polyimide film having a thickness of about 200 nm was obtained.

### Example 6

A mixed solution S4 containing PA2 95 g and PA5 5 g was spin-coated and baked at 220° C. for one hour in a glove box. With this a polyimide film having a thickness of about 200 nm was obtained.

### Comparative Example 1

A mixed solution S5 containing PA7 100 g was spin-coated and baked at 280° C. for one hour in a glove box. With this a polyimide film having a thickness of about 200 nm was obtained.

<Evaluation of Volume Resistivity>

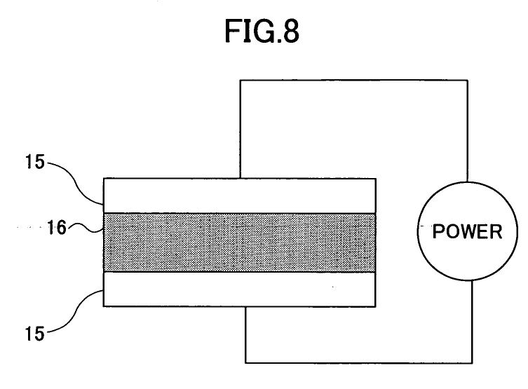

FIG. 8 shows the construction of the evaluation apparatus used for evaluating the volume resistivity. In this experiment, an electrode 15 of Au was formed on a film 16 to be evaluated by an evaporation deposition process with a diameter of 1 mm.

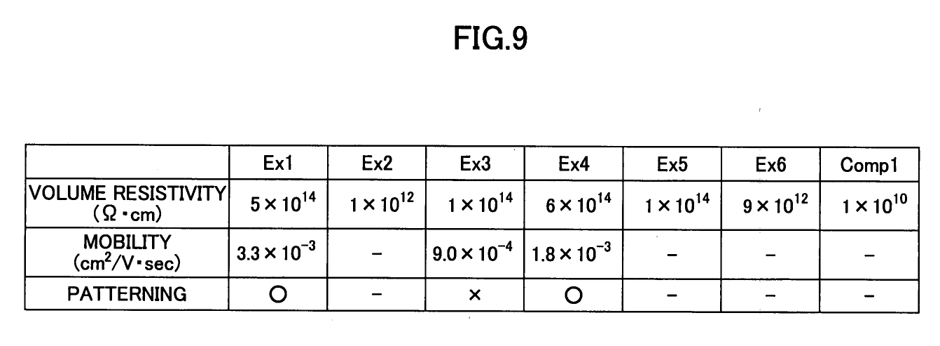

The electric characteristics of the films were evaluated according to the volume resistivity values calculated by the characteristic values obtained under the foregoing conditions. The result of the evaluation is summarized in FIG. 9.

Here, it should be noted that the film having good insulation performance has a volume resistivity of 1×10¹² Ωcm or more.

FIG. 9 indicates that the polyimide materials of Examples 1-4 have good insulation performance.

<Evaluation of Mobility>

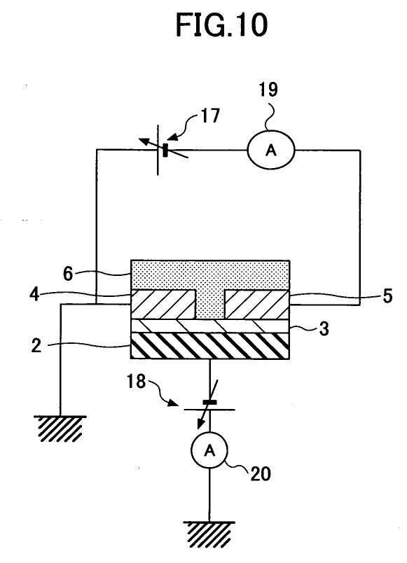

FIG. 10 shows the construction of the evaluation apparatus used for evaluating the mobility of the electron device together with the shape of the electron device of the present invention.

Referring to FIG. 10, an Au electrode deposited by an evaporation deposition process was used for the source and drain electrodes 4 and 5, and the electron device was formed to have a channel length of 50 μm±5 μm. Further, an Al electrode was used for the gate electrode 2, and the semiconductor layer 6 was formed by a hole-transporting compound represented by the structural formula of 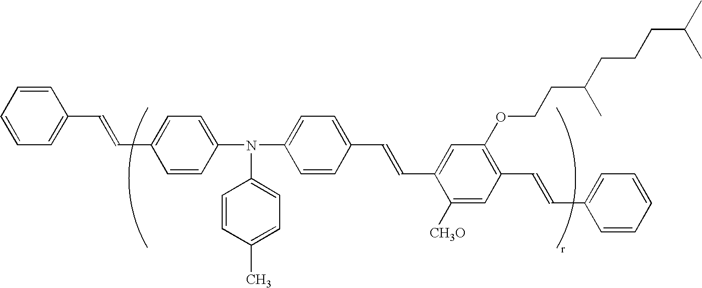
wherein the compound has a weight-average molecular weight of eighty thousand.

The insulation film 3 was formed with the thickness of 200 nm by applying S1, S3 and S4, followed by a baking process at 280° C. for one hour. Thereby, it should be noted that a first power supply 17 therein provides a voltage of 30V, while a second power supply 18 provides a voltage changed from +4 to −30V with a step of 1V.

FIG. 9 also shows the mobility thus evaluated for the semiconductor layers, wherein it is judged that the film provides satisfactory result when the value of the mobility is 1×10⁻⁴ cm²/V or more.

From FIG. 9, it can be seen that the semiconductor layers formed by the films of Examples 1, 3 and 4 provide satisfactory mobility.

<Evaluation of Patterning>

Further, FIG. 9 shows the evaluation of easiness of patterning. In this evaluation, instead of forming the Au electrodes for the source and drain electrodes 5 (second electrode layer) used in the case of measuring the mobility, the patterns corresponding to the second electrode layer are formed on the insulator layer by a masked exposure process that uses a UV light of the wavelength of 250 nm with the power of 9 mW/cm², followed by a film forming process of a polyethylenedioxy thiophene film on the exposed regions of the insulator film by an ink-jet process as the second electrode layer. Further, the patterns thus formed are observed by an optical microscope.

FIG. 9 shows the cases where all the patterns are formed according to the mask pattern with ◯; the cases in which there are some patterns not in conformity with the mask pattern by Δ; and the cases where the patterns cannot be formed according to the mask pattern with X.

From FIG. 9, it can be seen that the insulator layers of the Examples 1 and 4 can be patterned according to the mask pattern with the foregoing exposure and ink-jet process.

Further, the present invention is by no means limited to the embodiments described heretofore, but various variations and modifications may be made without departing from the scope of the invention.

The present invention is based on the

Japanese priority applications No. 2004-347044 filed on Nov. 30, 2004 and No. 2005-284928 filed on Sep. 29, 2005, the entire contents of which are incorporated herein as reference.

What is claimed is:

1. An electron device comprising at least an electrode layer, a semiconductor layer and an insulator layer laminated on a substrate,
said insulator layer containing a polyimide material obtained by using at least one of a polyamic acid and derivatives of said polyamic acid, said polyamic acid being obtained by reacting one or more of tetracarbonic acid dianhydride compounds selected from the group consisting of a tetracarbonic anhydride and derivatives of said tetracarbonic anhydride, with a diamine compound,
said tetracarbonic dianhydride compound containing one or more components of tetracarbonic dianhydride compound selected from the group consisting of tetracarbonic acid dianhydrides represented by structural formulae of: 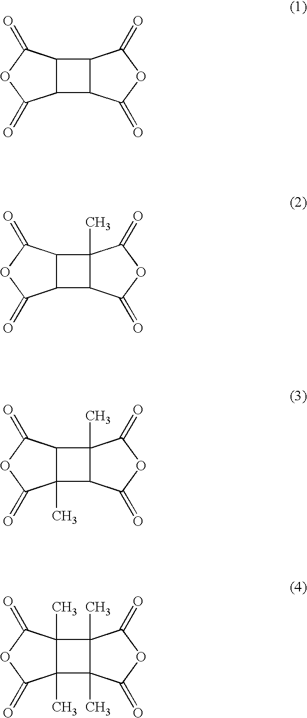 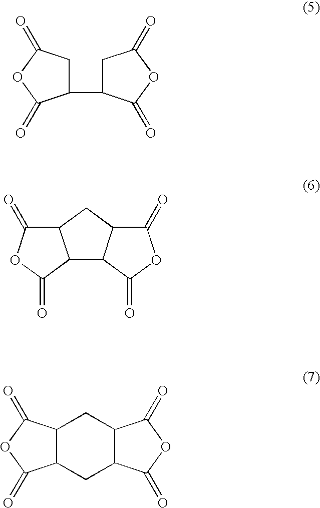 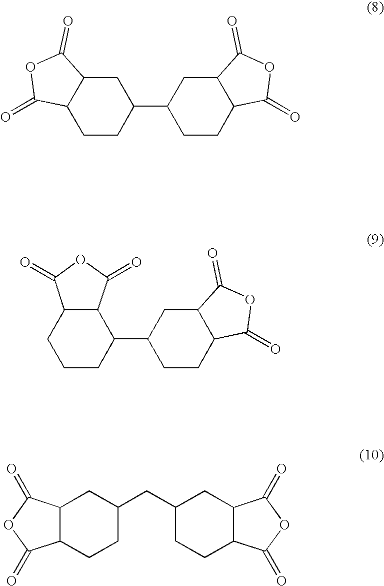 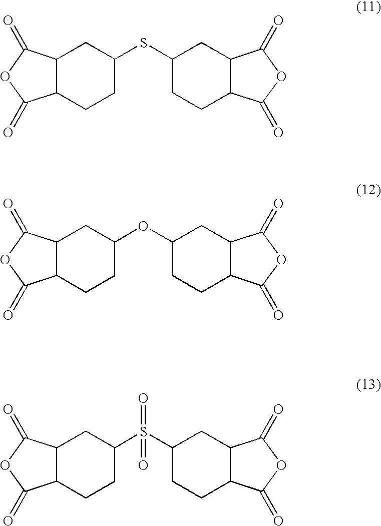 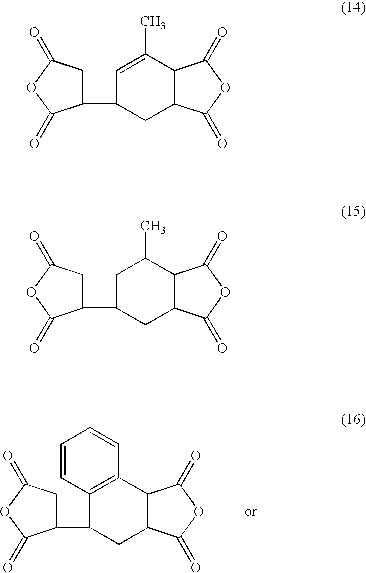 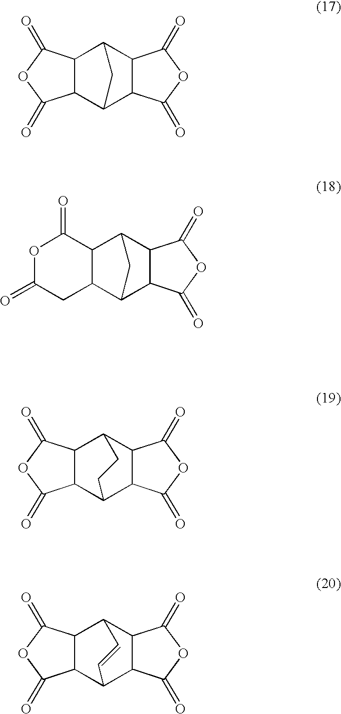 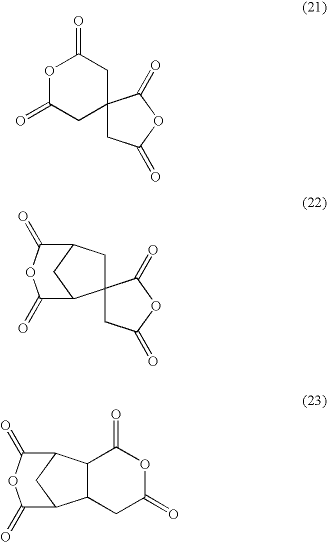 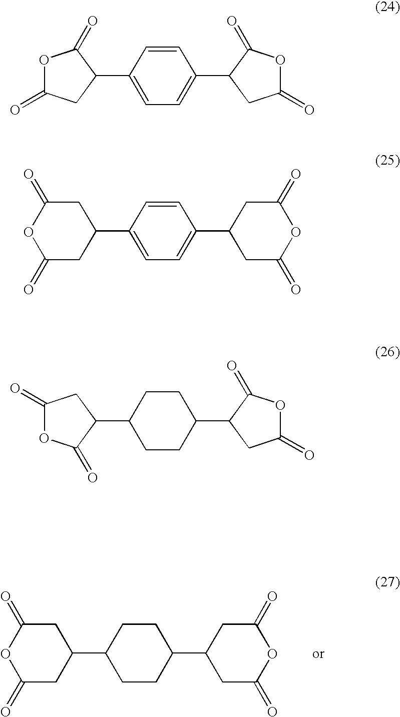 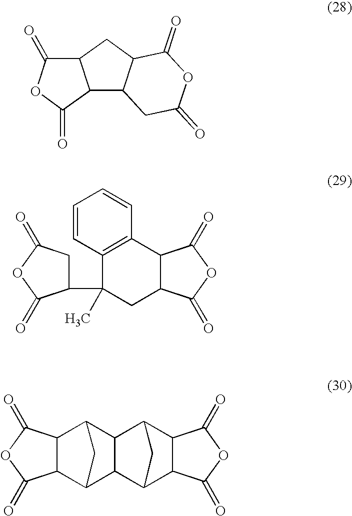 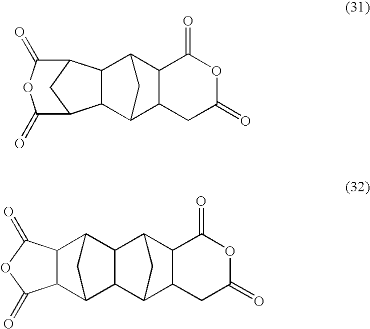 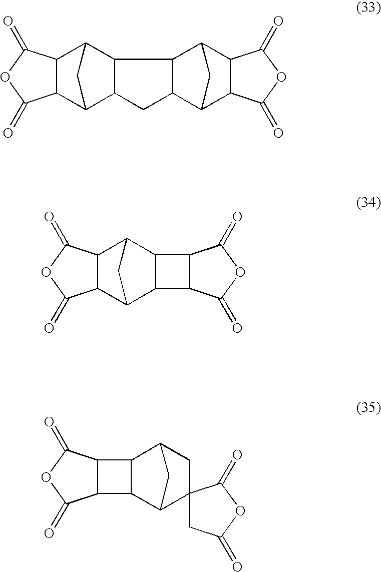 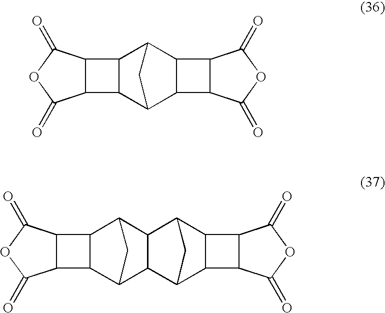
and derivatives of said tetracarbonic acid dianhydrides.

2. The electron device as claimed in claim 1, wherein said component of said tetracarbonic acid dianhydride compounds is contained with a mole fraction of 0.5 or more but not exceeding 1 with respect to said tetracarbonic acid dianhydride compounds.

3. An electron device comprising at least an electrode layer, a semiconductor layer and an insulator layer laminated on a substrate, said insulator layer containing a polyimide material obtained by using a polyamic acid or a derivative of said polyamic acid, said polyamic acid being obtained by causing to react one or more of tetracarbonic acid dianhydride compounds selected from the group consisting of a tetracarbonic acid dianhydride and a derivative of said tetracarbonic acid dianhydride with a diamine compound,
said tetracarbonic dianhydride compound containing one or more components of tetracarbonic dianhydride compound selected from the group consisting of tetracarbonic acid dianhydrides represented by structural formulae of: 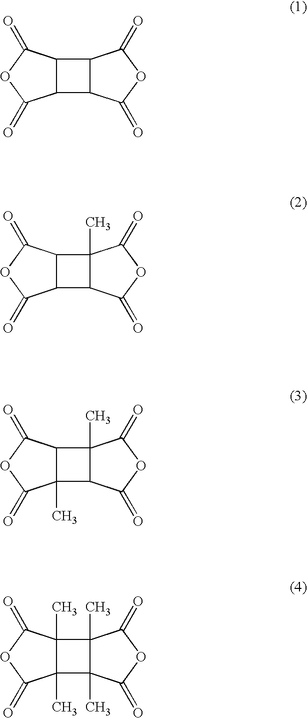 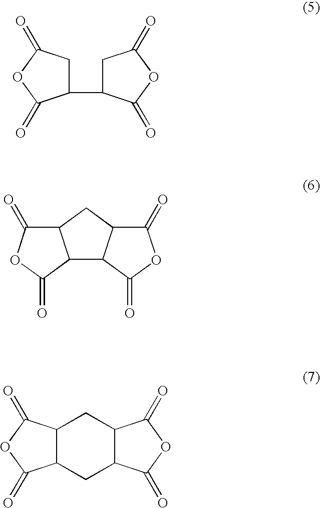 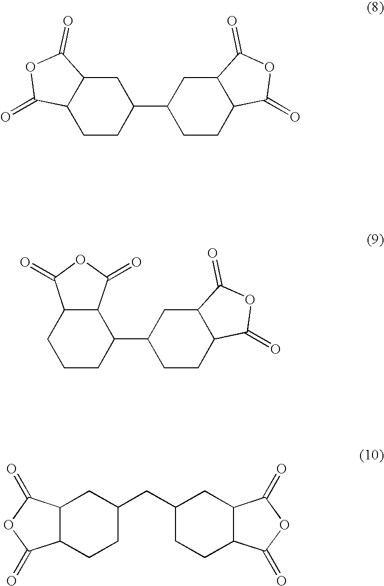 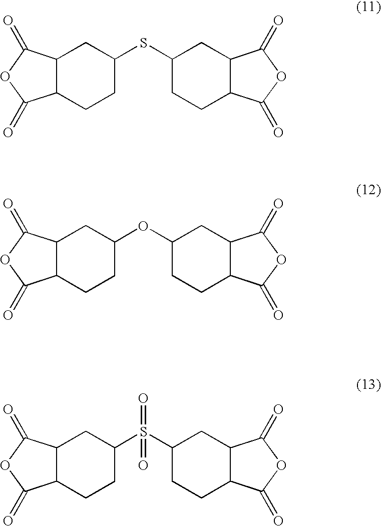 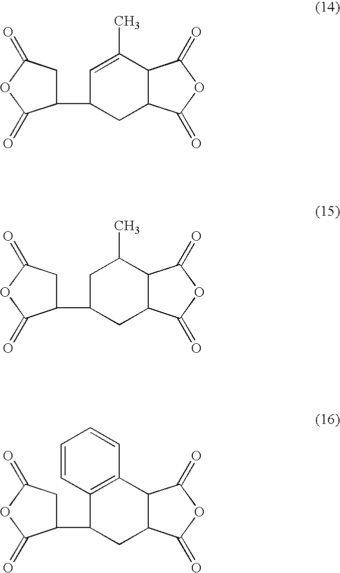 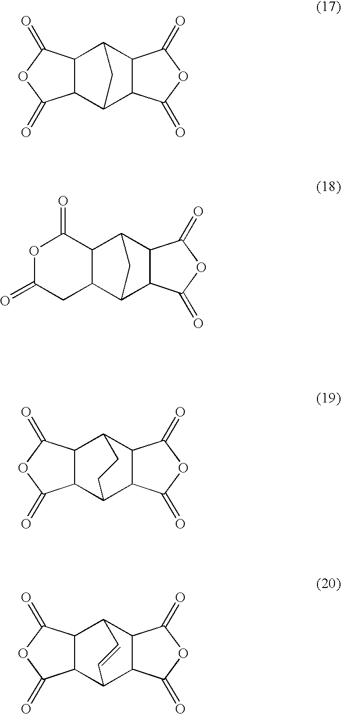 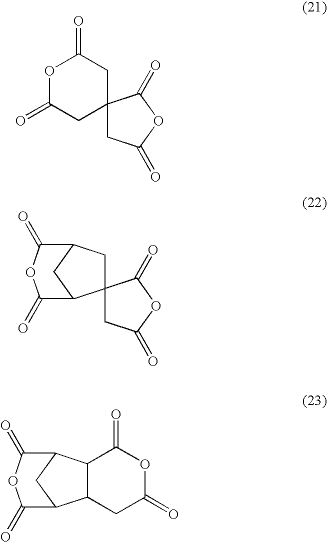 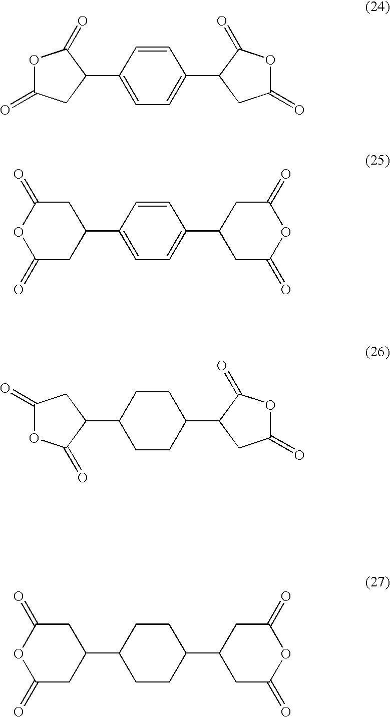 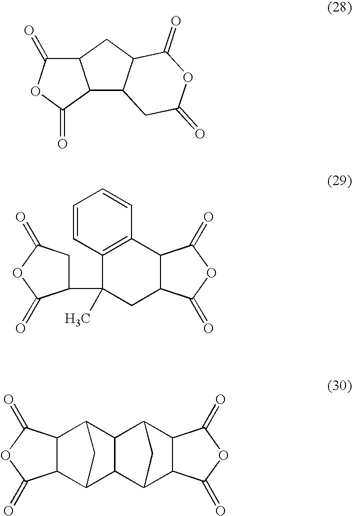 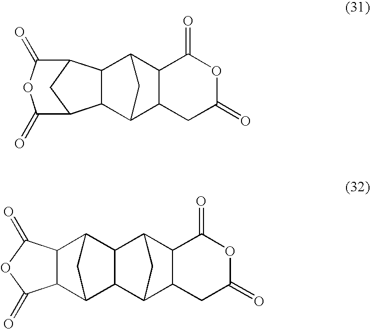 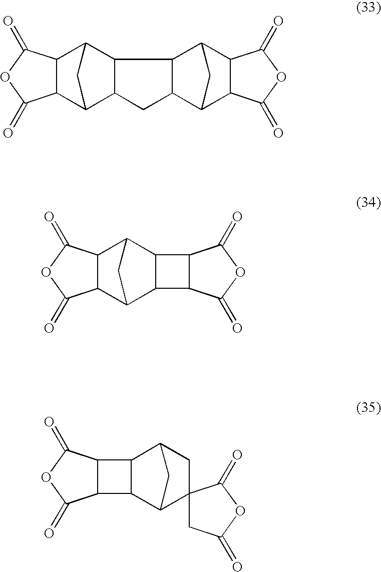 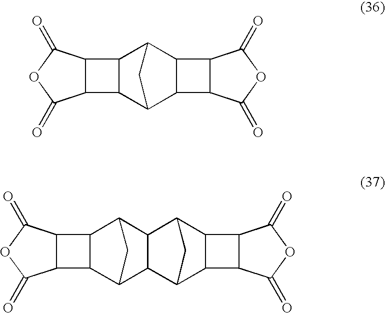
and derivatives of said tetracarbonic acid dianhydrides.
said diamine compound containing a diamine having a side chain.

4. The electron device as claimed in claim 3, wherein said diamine having a side chain comprises one or more compounds selected from the group of the compounds represented as 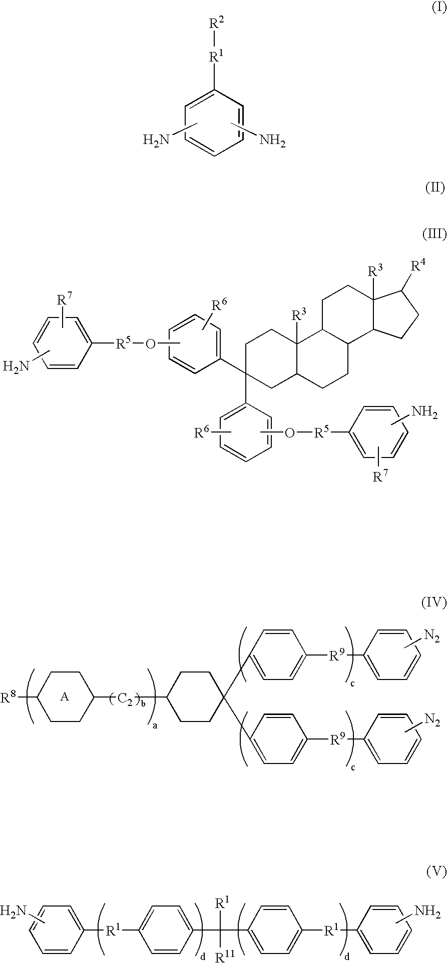
wherein R¹ is any of a single bond, an oxy group, a carbonyl group, —COO—, —OCO—, —CONH, —CH₂O—, CF₂O—, or —(CH₂)ₑ—,
R² is a group having a steroid structure and having a general formula of 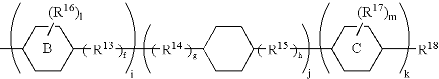
or an alkyl group or a phenyl group containing one or more but not exceeding twenty carbon atoms,
R³ is, independently in each occurrence, a hydrogen atom or a methyl group,
R⁴ is, independently in each occurrence thereof, a hydrogen atom or an alkyl group containing one or more, but not exceeding twenty, carbon atoms,
R⁵ is, independently in each occurrence thereof, any of a single bond, a carbonyl group or a methylene group,
each of R⁶ and R⁷ is, independently in each occurrence thereof, any of a hydrogen atom or an alkyl group or a phenyl group containing one or more, but not exceeding twenty, carbon atoms,
R⁸ is a hydrogen atom or an alkyl group containing one or more, but not exceeding twenty, carbon atoms,
R⁹ is, independently in each occurrence thereof, an oxy group or an alkylene group containing one or more, but not exceeding six, carbon atoms,
each of R¹⁰ and R¹¹ is, independently in each occurrence thereof, any of a hydrogen atom, an alkyl group or a perfluoroalkyl group having one or more, but not exceeding twenty, carbon atoms, at least one of R¹⁰ and R¹¹ being an alkyl group or a perfluoroalkyl group containing three or more carbon atoms,
R¹² is, independently in each occurrence thereof, an oxy group or an alkylene group containing one or more, but not exceeding six, carbon atoms,
each of R¹³, R¹⁴ and R¹⁵ is independently in each occurrence thereof, any of a single bond, an oxy group, —COO—, —OCO—, —CONH—, an alkylene group containing one or more, but not exceeding four, carbon atoms, or an alkyleneoxy group containing one or more, but not exceeding three, carbon atoms,
each of R¹⁶ and R¹⁷ is, independently in each occurrence thereof, any of a hydrogen atom, a fluoro group or a methyl group,
R¹⁸ is any of a hydrogen atom, a fluoro group, a chloro group, a cyano group, an alkyl group containing one or more, but not exceeding twenty, carbon atoms, an alkoxy group containing one or more, but not exceeding twenty, carbon atoms, an alkoxyalkyl group containing two or more, but not exceeding twenty, carbon atoms, a fluoromethyl group, a difluoromethyl group, a trifluoromethyl group, a fluoromethoxy group, difluoromethoxy group or a trifluoromethoxy group,
said ring A is any of a 1,4-phenylene group or 1,4-cyclohexylene group,
each of said rings B and C is any of a 1,4-phenylene group or 1,4-cyclohexylene group,
a is 0 or 1,
b is an integer of 0 or larger but not exceeding 2,
c is, independently in each occurrence thereof, an integer of 0 or 1,
d is, independently in each occurrence thereof, an integer of 0 or 1,
e is an integer of 1 or larger but not exceeding 6,
each of f, g and h is, independently in each occurrence thereof, an integer of 0 or larger but not exceeding 4,
each of i, j and k is, independently in each occurrence thereof, an integer of 0 or larger but not exceeding 3,
a total of i, j and k being 1 or larger,
each of 1 and m having, independently in each occurrence thereof, a value of any of 1 or 2.

5. The electron device as claimed in claim 3, wherein a mole fraction of said diamine having said side chain with regard to said diamine compounds is 0.3 or more nut not exceeding 1.

6. The electron device as claimed in claim 1, wherein said polyimide material is obtained by using at least one of said polyamic acid and said polyamic acid derivative and an imidation catalyst.

7. The electron device as claimed in claim 1, wherein said semiconductor layer comprises an organic semiconductor material.

8. The electron device as claimed in claim 1, wherein said electrode layer includes a first electrode layer and a second electrode layer, said second electrode layer comprising a pair of electrode patterns disposed with a mutual separation from each other, said first electrode layer, said insulator layer, said second electrode layer and said semiconductor layer are laminated consecutively over said substrate,
said electrode patterns of said second electrode layer being formed in correspondence to a region of said insulator layer provided with energy and having a larger critical surface tension as compared with a region not provided with said energy.

9. The electron device as claimed in claim 8, wherein said insulator layer comprises two or more polyimide materials, such that said insulator layer has a concentration gradient of polyimide in a thickness direction thereof.

10. The electron device as claimed in claim 1, wherein said insulator layer comprises a first insulator layer and a second insulator layer, said electrode layer comprises a first electrode layer including a pair of electrode patterns disposed with a mutual separation from each other and a second electrode layer, said first insulator layer, said electrode patterns of said first electrode layer, said semiconductor layer, said second insulator layer and said second electrode layer are laminated consecutively over said substrate,
wherein said first electrode layer is formed on said first insulator layer in correspondence to a region thereof where energy is provided and having a higher surface tension as compared with a region not provided with said energy.

11. The electron device as claimed in claim 10, wherein said first insulator layer comprises two or more polyimide materials, said first insulator layer having a concentration gradient of polyimide in a thickness direction thereof.

12. The electron device as claimed in claim 8, wherein said energy is provided by ultraviolet radiation.

13. The electron device as claimed in claim 8, wherein at least one of said first electrode layer and said second electrode layer is formed by an ink-jet process.

14. The electron device as claimed in claim 1, wherein said electron device forms an operational device.

15. The electron device as claimed in claim 1, wherein said electron device forms a display device.

16. The electron device as claimed in claim 3, wherein said polyimide material is obtained by using at least one of said polyamic acid and said polyamic acid derivative and an imidation catalyst.

17. The electron device as claimed in claim 3, wherein said semiconductor layer comprises an organic semiconductor material.

18. The electron device as claimed in claim 3, wherein said electrode layer includes a first electrode layer and a second electrode layer, said second electrode layer comprising a pair of electrode patterns disposed with a mutual separation from each other, said first electrode layer, said insulator layer, said second electrode layer and said semiconductor layer are laminated consecutively over said substrate,
said electrode patterns of said second electrode layer being formed in correspondence to a region of said insulator layer provided with energy and having a larger critical surface tension as compared with a region not provided with said energy.

19. The electron device as claimed in claim 18, wherein said insulator layer comprises two or more polyimide materials, such that said insulator layer has a concentration gradient of polyimide in a thickness direction thereof.

20. The electron device as claimed in claim 3, wherein said insulator layer comprises a first insulator layer and a second insulator layer, said electrode layer comprises a first electrode layer including a pair of electrode patterns disposed with a mutual separation from each other and a second electrode layer, said first insulator layer, said electrode patterns of said first electrode layer, said semiconductor layer, said second insulator layer and said second electrode layer are laminated consecutively over said substrate,
wherein said first electrode layer is formed on said first insulator layer in correspondence to a region thereof where energy is provided and having a higher surface tension as compared with a region not provided with said energy.

21. The electron device as claimed in claim 20, wherein said first insulator layer comprises two or more polyimide materials, said first insulator layer having a concentration gradient of polyimide in a thickness direction thereof.

22. The electron device as claimed in claim 18, wherein said energy is provided by ultraviolet radiation.

23. The electron device as claimed in claim 18, wherein at least one of said first electrode layer and said second electrode layer is formed by an ink-jet process.

24. The electron device as claimed in claim 3, wherein said electron device forms an operational device.

25. The electron device as claimed in claim 3, wherein said electron device forms a display device.
